(19) United States
(12) Patent Application Publication
(10) Pub. No.: US 2026/0323961 A1
(43) Pub. Date: Oct. 15, 2026

(54) SEMICONDUCTOR MEMORY DEVICE

(71) Applicant: SAMSUNG ELECTRONICS CO., LTD., Suwon-si (KR)

(72) Inventors: Yujin KIM, Suwon-si (KR); Jinwoo HAN, Suwon-si (KR); Juhyun KIM, Suwon-si (KR); Hyeoncheol KIM, Suwon-si (KR)

(73) Assignee: SAMSUNG ELECTRONICS CO., LTD., Suwon-si (KR)

(21) Appl. No.: 19/464,726

(22) Filed: Jan. 30, 2026

(30) Foreign Application Priority Data
Mar. 4, 2025 (KR) 10-2025-0027755

(51) Int. Cl. H10B 80/00; G11C 11/4091; H10B 12/00; H10W 90/00; H10W 90/26

(52) U.S. Cl. CPC H10B 80/00; G11C 11/4091; H10B 12/30; H10B 12/50; H10W 90/26; H10W 90/792

(57) ABSTRACT

A semiconductor memory device includes a memory cell structure including a plurality of memory cells configured by a plurality of semiconductor patterns, a plurality of word lines, a plurality of bit lines, and a plurality of information storage elements, a peripheral circuit structure stacked in a vertical direction with respect to the memory cell structure and including a plurality of peripheral circuit transistors configuring a sense amplifier, and a first multiplexer and a second multiplexer each connected to the sense amplifier, and a bonding structure between the memory cell structure and the peripheral circuit structure to bond the memory cell structure to the peripheral circuit structure. The first multiplexer is electrically connected to at least two bit lines, and the second multiplexer is electrically connected to at least two other bit lines among the plurality of bit lines.

### CROSS-REFERENCE TO RELATED APPLICATION

This application is based on and claims priority under 35 U.S.C. § 119 to Korean Patent Application No. 10-2025-0027755, filed on Mar. 4, 2025, in the Korean Intellectual Property Office, the disclosure of which is incorporated by reference herein in its entirety.

### BACKGROUND

The inventive concept relates to a semiconductor memory device, and more particularly, to a three-dimensional (3D) semiconductor memory device.

To meet the need for miniaturized, multifunctional, and high-performance electronic products, high-capacity semiconductor memory devices are needed, and in order to provide high-capacity semiconductor memory devices, an increased degree of integration is needed. Because the degree of integration of two-dimensional (2D) semiconductor memory devices of the related art is mainly determined based on the area occupied by a unit memory cell, the degree of integration of 2D semiconductor memory devices is increasing, but is still limited. Therefore, 3D semiconductor memory devices have been proposed where a memory capacity increases by stacking a plurality of memory cells on a substrate in a vertical direction.

### SUMMARY

The inventive concept provides a three-dimensional (3D) semiconductor memory device in which operation reliability and the degree of integration are enhanced.

A semiconductor memory device according to an embodiment includes a memory cell structure including a plurality of memory cells configured by a plurality of semiconductor patterns, a plurality of word lines adjacent to the plurality of semiconductor patterns, a plurality of bit lines connected to the plurality of semiconductor patterns, and a plurality of information storage elements connected to the plurality of semiconductor patterns, the plurality of information storage elements arranged to configure a column in each of a first horizontal direction, a second horizontal direction perpendicular to the first horizontal direction, and a vertical direction, a peripheral circuit structure stacked in the vertical direction with respect to the memory cell structure and including a plurality of peripheral circuit transistors configuring a sense amplifier, and a first multiplexer and a second multiplexer each connected to the sense amplifier, and a bonding structure including a bonding insulation layer and a plurality of circuit cell connection structures passing through the bonding insulation layer, and disposed between the memory cell structure and the peripheral circuit structure to bond the memory cell structure to the peripheral circuit structure. The first multiplexer is electrically connected to at least two bit lines among the plurality of bit lines through one or more of the plurality of circuit cell connection structures, and the second multiplexer is electrically connected to at least two other bit lines among the plurality of bit lines through another one or more of the plurality of circuit cell connection structures.

A semiconductor memory device according to an embodiment includes a memory cell structure including a plurality of memory cells configured by a plurality of word lines each extending in a first horizontal direction and arranged apart from one another to configure a column in each of a second horizontal direction perpendicular to the first horizontal direction and a vertical direction, a plurality of bit lines each extending in the vertical direction and arranged apart from one another to configure a column in each of the first horizontal direction and the second horizontal direction, a plurality of cell transistors disposed between the plurality of word lines and the plurality of bit lines and connected to the plurality of bit lines, and a plurality of information storage elements connected to the plurality of cell transistors, a peripheral circuit structure stacked in the vertical direction with respect to the memory cell structure and including a plurality of peripheral circuit transistors configuring a sense amplifier, and a first multiplexer and a second multiplexer each connected to the sense amplifier, and a bonding structure including a bonding insulation layer and a plurality of circuit cell connection structures passing through the bonding insulation layer, and disposed between the memory cell structure and the peripheral circuit structure to bond the memory cell structure to the peripheral circuit structure. The first multiplexer is electrically connected to at least two bit lines among the plurality of bit lines through one or more of the plurality of circuit cell connection structures, and the second multiplexer is electrically connected to at least two other bit lines among the plurality of bit lines through another one or more of the plurality of circuit cell connection structures.

A semiconductor memory device according to an embodiment includes a memory cell structure including a plurality of memory cells configured by a plurality of word lines each extending in a first horizontal direction and arranged apart from one another to configure a column in each of a second horizontal direction perpendicular to the first horizontal direction and a vertical direction, a plurality of semiconductor patterns which are adjacent to the plurality of word lines, each extend in the second horizontal direction, and are arranged to configure a column in each of the first horizontal direction, the second horizontal direction, and the vertical direction, a plurality of bit lines which each extend in the vertical direction, are arranged apart from one another to configure a column in each of the first horizontal direction and the second horizontal direction, and are connected to ends of the plurality of semiconductor patterns in the second horizontal direction, and a plurality of information storage elements connected to other ends of the plurality of semiconductor patterns, a peripheral circuit structure stacked in the vertical direction with respect to the memory cell structure and including a peripheral circuit substrate, a device isolation insulation layer buried in the peripheral circuit substrate and a plurality of peripheral circuit transistors disposed in portions of the peripheral circuit substrate defined by the device isolation insulation layer, the plurality of peripheral circuit transistors configuring a sense amplifier, and a first multiplexer and a second multiplexer each connected to the sense amplifier, and a bonding structure including a bonding insulation layer and a plurality of circuit cell connection structures which pass through the bonding insulation layer, extend in the vertical direction to each of the memory cell structure and the peripheral circuit structure, and disposed between the memory cell structure and the peripheral circuit structure to bond the memory cell structure to the peripheral circuit structure. The first multiplexer is electrically connected to at least two bit lines among the plurality of bit lines through one or more of the plurality of circuit cell connection structures, and the second multiplexer is electrically connected to at least two other bit lines among the plurality of bit lines through another one or more of the plurality of circuit cell connection structures.

### BRIEF DESCRIPTION OF THE DRAWINGS

Embodiments will be more clearly understood from the following detailed description taken in conjunction with the accompanying drawings in which:

FIG. 1 is an equivalent circuit diagram illustrating a memory cell array of a semiconductor memory device according to embodiments;

FIG. 2 is a block diagram describing a semiconductor memory device according to embodiments;

FIG. 3 is a diagram describing a semiconductor memory device according to embodiments;

FIG. 4 is a perspective view illustrating a semiconductor memory device according to embodiments;

FIGS. 5A and 5B are a perspective view and a cross-sectional view illustrating a portion of a semiconductor memory device according to embodiments;

FIGS. 6A and 6B are cross-sectional views illustrating a semiconductor memory device according to embodiments;

FIGS. 7A and 7B are cross-sectional views illustrating a semiconductor memory device according to embodiments;

FIG. 8 is a diagram describing a semiconductor memory device according to embodiments;

FIG. 9 is an equivalent circuit diagram illustrating a memory cell array of a semiconductor memory device according to embodiments;

FIGS. 10A and 10B are a perspective view and a cross-sectional view illustrating a portion of a semiconductor memory device according to embodiments;

FIG. 11 is a diagram for describing a semiconductor memory device according to embodiments;

FIG. 12 is a diagram for describing a semiconductor memory device according to embodiments;

FIG. 13 is a diagram for describing a method of manufacturing a semiconductor memory device, according to embodiments;

FIGS. 14A, 14B, 15A, and 15B are cross-sectional views for describing a method of manufacturing a semiconductor memory device, according to embodiments; and

FIGS. 16A, 16B, 17A, and 17B are cross-sectional views for describing a method of manufacturing a semiconductor memory device, according to embodiments.

### DETAILED DESCRIPTION OF THE EMBODIMENTS

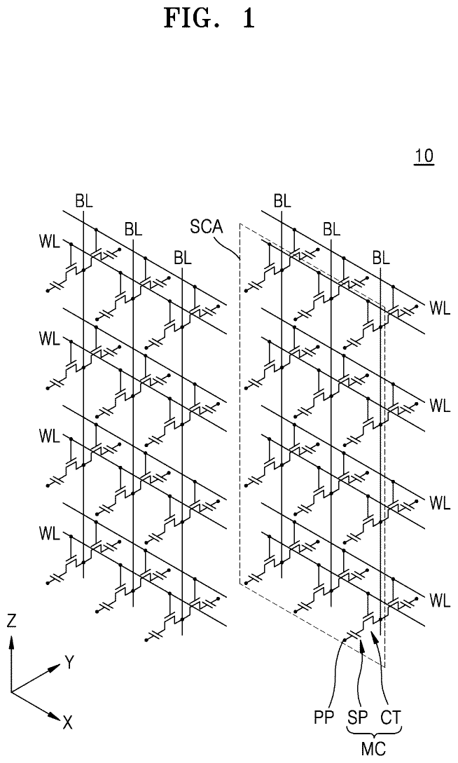

FIG. 1 is an equivalent circuit diagram illustrating a memory cell array of a semiconductor memory device 10 according to embodiments.

Referring to FIG. 1, the memory cell array of the semiconductor memory device 10 according to embodiments may include a plurality of sub cell arrays SCA. The sub cell array SCA may include a plurality of bit lines BL, a plurality of word lines WL, and a plurality of memory cells MC. Each of the plurality of memory cells MC may include a cell transistor CT and an information storage element SP. One cell transistor CT may be disposed between one word line WL and one bit line BL. The information storage element SP may be a memory element which may store data.

The word line WL may be a conductive pattern (for example, a metal line) which is apart from a substrate and is disposed on the substrate. Each of the plurality of word lines WL may extend in a first horizontal direction (an X direction). Word lines WL of one sub cell array SCA may be apart from each other in a vertical direction (a Z direction). Each of the bit lines BL may extend in the vertical direction (the Z direction) from the substrate. Bit lines BL of one sub cell array SCA may be apart from each other in the first horizontal direction (the X direction).

In the memory cell array of the semiconductor memory device 10, the plurality of word lines WL may extend in the first horizontal direction (the X direction) and may be apart from each other in each of a second horizontal direction (a Y direction) and the vertical direction (the Z direction). In the memory cell array of the semiconductor memory device 10, the plurality of bit lines BL may extend in the vertical direction (the Z direction) and may be apart from each other in each of the first horizontal direction (the X direction) and the second horizontal direction (the Y direction).

In some embodiments, the information storage element SP may be a memory element using a capacitor, a memory element using a magnetic tunnel junction pattern, or a memory element using a variable resistor including a phase change material. For example, the memory cell MC may be dynamic random access memory (RAM) (DRAM), and the information storage element SP may be a capacitor. In other embodiments, the information storage element SP may be a transistor which may store data along with the cell transistor CT.

In the second horizontal direction (the Y direction), the bit line BL may be connected to one end of the cell transistor CT, and the information storage element SP may be connected to the other end of the cell transistor CT. A gate of the cell transistor CT may be connected to the word line WL, and the bit line BL may be connected to a source region of the cell transistor CT. The information storage element SP may be connected to a drain region of the cell transistor CT. In some embodiments, the information storage element SP may be a capacitor including a first electrode, a second electrode, and a capacitor dielectric layer disposed between the first electrode and the second electrode, and the first electrode of the capacitor may be connected to the drain region of the cell transistor CT.

The memory cell array of the semiconductor memory device 10 may include the plurality of memory cells MC which are apart from each other in each of the first horizontal direction (the X direction) and the vertical direction (the Z direction) and are disposed to configure rows and columns, the plurality of bit lines BL which are connected to cell transistors CT of memory cells MC disposed in the vertical direction (the Z direction), extend in the vertical direction (the Z direction), and are disposed apart from each other in the first horizontal direction (the X direction), and the plurality of sub cell arrays SCA each including a plurality of word lines WL which extend in the first horizontal direction (the X direction) and are disposed apart from each other in the vertical direction (the Z direction), and the plurality of sub cell arrays SCA may be arranged in the second horizontal direction (the Y direction). The semiconductor memory device 10 may include a plurality of memory cell arrays. The semiconductor memory device 10 may be a three-dimensional (3D) semiconductor memory device including memory cells MC which are arranged to configure a row in each of the first horizontal direction (the X direction), the second horizontal direction (the Y direction), and the vertical direction (the Z direction).

The first horizontal direction (the X direction), the second horizontal direction (the Y direction), and the vertical direction (the Z direction) may be respectively referred to as a first direction, a second direction, and a third direction. Alternatively, the first horizontal direction (the X direction), the vertical direction (the Z direction), and the second horizontal direction (the Y direction) may be respectively referred to as a first direction, a second direction, and a third direction. The first direction, the second direction, and the third direction may be perpendicular to one another.

Two sub cell arrays SCA adjacent to each other in the second horizontal direction (the Y direction) may share bit lines BL. Source regions of cell transistors CT included in each of the two sub cell arrays SCA may be connected to bit lines BL shared by the two sub cell arrays SCA adjacent to each other in the second horizontal direction (the Y direction). A source region and a drain region of a cell transistor CT of each of the two sub cell arrays SCA and the information storage element SP may be arranged in opposite directions from the bit lines BL shared by the two sub cell arrays SCA. For example, a cell transistor CT of one sub cell array SCA of two sub cell arrays SCA and a cell transistor CT of the other sub cell array SCA may be connected to one bit line BL shared by two sub cell arrays SCA. A source region of a cell transistor CT, a drain region of the cell transistor CT, and an information storage element SP in one sub cell array SCA may be sequentially arranged in the second horizontal direction (the Y direction). A source region of a cell transistor CT, a drain region of the cell transistor CT, and an information storage element SP in the other sub cell array SCA may be sequentially arranged in a direction opposite to the second horizontal direction (the Y direction). For example, two memory cells MC may be arranged in the second horizontal direction (the Y direction) at the same vertical level, between a pair of bit lines BL sequentially arranged adjacent to each other in the second horizontal direction (the Y direction) among the plurality of bit lines BL.

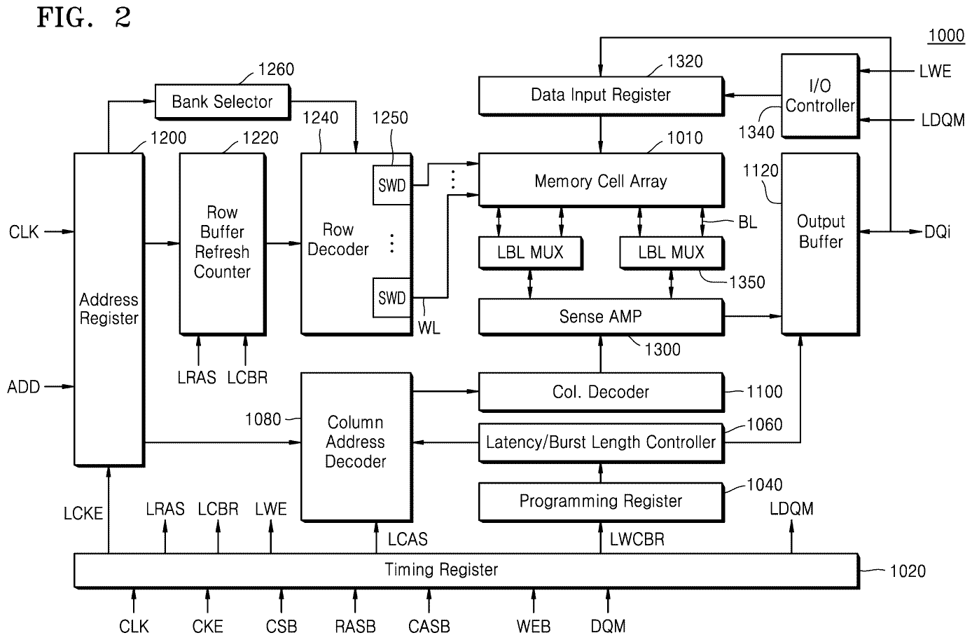

FIG. 2 is a block diagram for describing a semiconductor memory device 1000 according to embodiments.

Referring to FIG. 2, the semiconductor memory device 1000 may include a memory cell array 1010 including a DRAM cell which is a memory cell and various circuit blocks for driving the DRAM cell. The memory cell array 1010 may include a plurality of sub cell arrays SCA each including the plurality of memory cells MC illustrated in FIG. 1. For example, a timing register 1020 may be activated when a chip selection signal CSB is shifted from a non-active level (for example, logic high) to an active level (for example, logic low). The timing register 1020 may receive a command signal such as a clock signal CLK, a clock enable signal CKE, a chip selection signal CSB, a row address strobe signal RASB, a column address strobe signal CASB, a write enable signal WEB, and a data input/output mask signal DQM from the outside and may process the received command signal to generate various internal command signals LCKE, LRAS, LCBR, LWE, LCAS, LWCBR, and LDQM for controlling circuit blocks.

Some internal command signals generated from the timing register 1020 may be stored in a programming register 1040. For example, latency information or burst length information associated with a data output may be stored in the programming register 1040. The internal command signals stored in the programming register 1040 may be provided to a latency/burst length controller 1060, and the latency/burst length controller 1060 may provide a control signal, which is for controlling a latency or a burst length of a data output, to a column decoder 1100 or an output buffer 1120 through a column address buffer 1080.

The address register 1200 may receive the clock signal CLK and the address signal ADD from the outside. The row address signal may be provided to a row decoder 1240 through a row address buffer 1220. Also, the column address signal may be provided to the column decoder 1100 through the column address buffer 1080. In response to refresh commands LRAS and LCBR, the row address buffer 1220 may further receive a refresh address signal generated in a refresh counter and may provide one of the row address signal and the refresh address signal to the row decoder 1240. Also, the address register 1200 may provide a bank selector 1260 with a bank signal for selecting a bank.

The row decoder 1240 may decode the row address signal or the refresh address signal input from the row address buffer 1220. The row decoder 1240 may include a plurality of sub word line drivers 1250. The sub word line driver 1250 may activate the word line WL of the memory cell array 1010. The sub word line driver 1250 may be arranged by block units at a certain interval in the row decoder 1240 so as to be adjacent to the memory cell array 1010. For example, the sub word line driver 1250 may be disposed adjacent to one end of the memory cell array 1010 to be perpendicular to a sense amplifier 1300.

The column decoder 1100 may decode the column address signal and may perform a selection operation on the bit line BL of the memory cell array 1010. For example, a column selection line may be applied to the semiconductor memory device 1000, and a selection operation based on the column selection line may be performed.

The sense amplifier 1300 may amplify data of a memory cell selected by the row decoder 1240 and the column decoder 1100 and may provide amplified data to the output buffer 1120. Two multiplexers 1350 may be connected to the sense amplifier 1300. The multiplexer 1350 may be referred to as a local bit line LBL multiplexer. At least two bit lines BL may be respectively connected to the two multiplexers 1350. The sense amplifier 1300 may be connected to at least four bit lines BL through the two multiplexers 1350. The output buffer 1120 may output output data DQi. The output data DQi to be recorded in a memory cell may be provided to the memory cell array 1010 through the data input register 1320, and an input/output (I/O) controller 1340 may control a data transfer operation based on the data input register 1320.

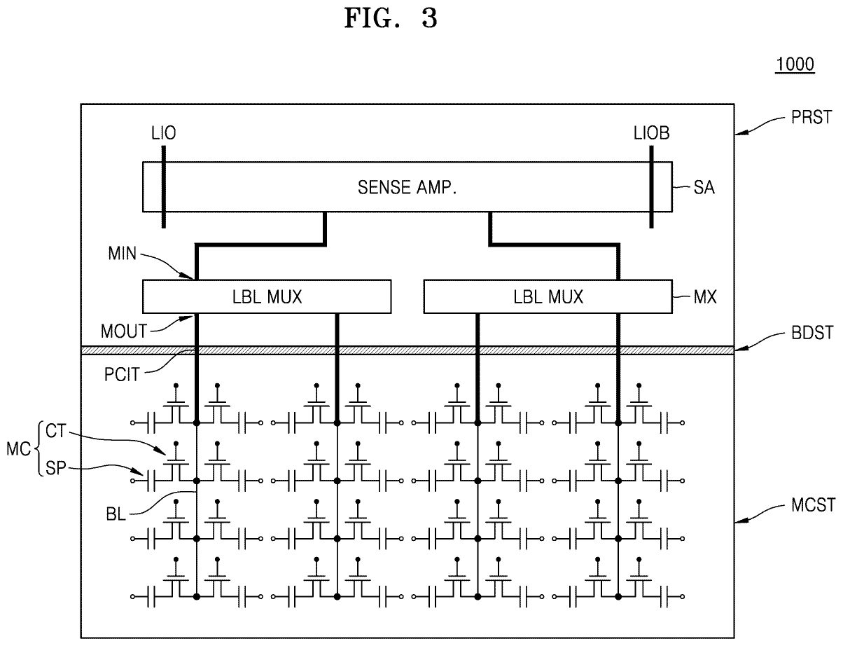

FIG. 3 is a diagram for describing a semiconductor memory device 1000 according to embodiments.

Referring to FIG. 3, the semiconductor memory device 1000 may include a memory cell structure MCST and a peripheral circuit structure PRST, which are stacked in a vertical direction (a Z direction). A bonding structure BDST may be disposed between the memory cell structure MCST and the peripheral circuit structure PRST.

Each of the memory cell structure MCST, the peripheral circuit structure PRST, and the bonding structure BDST may be an arbitrary division based on convenience of description and a functional difference, and thus, a division between structures may not be clear. In FIG. 3, it is illustrated that the semiconductor memory device 1000 has a periphery on cell (PoC) structure including the peripheral circuit structure PRST disposed on the memory cell structure MCST, but this may be an embodiment and the inventive concept is not limited thereto. For example, the semiconductor memory device 1000 may have a cell on periphery (CoP) structure including the memory cell structure MCST disposed on the peripheral circuit structure PRST.

In some embodiments, after a first wafer including a plurality of memory cell structures MCST are formed, a second wafer including a plurality of peripheral circuit structures PRST may be bonded onto the first wafer, and a plurality of semiconductor memory devices 1 each including a memory cell structure MCST and a peripheral circuit structure PRST corresponding to each other may be formed by dicing a stack structure of the first wafer and the second wafer. In some embodiments, the second wafer including some of the plurality of peripheral circuit structures PRST may be bonded onto the first wafer including the plurality of memory cell structures MCST, and the other peripheral circuit structures PRST may be formed in the stack structure of the first wafer and the second wafer, and then, the plurality of semiconductor memory devices 1 each including a memory cell structure MCST and a peripheral circuit structure PRST corresponding to each other may be formed by dicing the stack structure of the first wafer and the second wafer. A portion of the bonding structure BDST may be formed in the first wafer, and the other portion thereof may be formed in the second wafer, and then, the portion and the other portion of the bonding structure BDST may configure the bonding structure BDST.

The memory cell structure MCST and the peripheral circuit structure PRST may be electrically connected to each other by a circuit cell connection structure PCIT. Each of a plurality of circuit cell connection structures PCIT may pass through the bonding structure BDST and may extend into each of the memory cell structure MCST and the peripheral circuit structure PRST.

The memory cell structure MCST may include a plurality of memory cells MC. The plurality of memory cells MC included in the memory cell structure MCST, as illustrated in FIG. 1, may be three-dimensionally arranged to configure a column in each of a first horizontal direction (an X direction), a second horizontal direction (a Y direction), and a vertical direction (a Z direction). Each of the plurality of memory cells MC may include a cell transistor CT and an information storage element SP. The bit line BL may be connected to a source region of the cell transistor CT, and the information storage element SP may be connected to a drain region of the cell transistor CT.

The peripheral circuit structure PRST may include a plurality of peripheral circuit transistors. The plurality of peripheral circuit transistors may be configured to transfer a signal and/or power to a plurality of memory cells included in the memory cell structure MCST. For example, the plurality of peripheral circuit transistors may configure various circuits such as a command decoder, a control logic, an address buffer, a row decoder, a column decoder, a sense amplifier SA, a multiplexer MX, and a data I/O circuit. In FIG. 3, the sense amplifier SA and the multiplexer MX of the various circuits configured by the plurality of peripheral circuit transistors are illustrated.

A local I/O line LIO and a local I/O line bar LIOB may be connected to the sense amplifier SA. The sense amplifier SA may be connected to the plurality of memory cells MC. A plurality of sense amplifiers SA may be electrically connected to two bit lines BL among a plurality of bit lines BL. One of two bit lines BL electrically connected to the sense amplifier SA may be a bit line BL which selects a memory cell MC so as to read stored data or write data, and the other bit line BL may be a bit line BL to which a reference voltage has been supplied, namely, a bit line BL which does not select a memory cell MC. A bit line BL to which the reference voltage has been supplied may be referred as a bit line bar or a BL bar. The multiplexer MX may be disposed between the sense amplifier SA and the bit line BL. Two multiplexers MX may be connected to one sense amplifier SA. The multiplexer MX may be referred to as a local bit line LBL multiplexer. One of two multiplexers MX connected to one sense amplifier SA may be referred to as a first multiplexer, and the other multiplexer MX may be referred to as a second multiplexer. That is, one sense amplifier SA may be connected to two multiplexers MX including the first multiplexer and the second multiplexer. The first multiplexer which is one of two multiplexers MX connected to one sense amplifier SA may be electrically connected to one bit line BL which selects a memory cell MC so as to read stored data or write data, and the second multiplexer which is the other multiplexer MX may be electrically connected to a bit line BL to which the reference voltage has been supplied. That is, one sense amplifier SA may be electrically connected to a bit line BL selected through two multiplexers MX and the bit line BL to which the reference voltage has been supplied.

The multiplexer MX may include one sense amplifier connection terminal MIN and at least two bit line connection terminals MOUT. The sense amplifier connection terminal MIN of the multiplexer MX may be connected to the sense amplifier SA, and the bit line connection terminal MOUT of the multiplexer MX may be connected to the bit line BL. The bit line connection terminal MOUT of the multiplexer MX and the bit line BL may be connected to each other through the circuit cell connection structure PCIT. When the multiplexer MX is a 2*1 multiplexer, the multiplexer MX may include two bit line connection terminals MOUT and may be connected to two bit lines BL, and moreover, may be electrically connected to one bit line BL selected from among the two bit lines BL. Therefore, the sense amplifier SA may be connected to at least four bit lines BL through two multiplexers MX and may be electrically connected to two bit lines BL which are selected by the two multiplexers MX from among the at least four bit lines BL. The semiconductor memory device 1000 may include one sense amplifier SA per four bit lines BL. That is, the number of sense amplifiers SA included in the semiconductor memory device 1000 may be ¼ of the number of bit lines BL. One of two bit lines BL electrically connected to the sense amplifier SA may be one bit line BL which is selected for reading or writing data, and the other bit line BL may be a bit line BL to which the reference voltage has been supplied.

The semiconductor memory device 1000 according to an embodiment may include a memory cell structure MCST and a peripheral circuit structure PRST, which are stacked in a vertical direction (a Z direction), and thus, the number of memory cells MC which may be one-dimensionally disposed in the same area may increase. Also, the sense amplifier SA and the multiplexer MX may be disposed in the peripheral circuit structure PRST, and the number of peripheral circuit transistors for configuring two multiplexers MX may be less than the number of peripheral circuit transistors for configuring one sense amplifier SA, and thus, even when more memory cells MC are disposed in the same area in the semiconductor memory device 1000, more sense amplifiers SA corresponding to memory cells MC may be disposed. Accordingly, the degree of integration of the semiconductor memory device 1000 may be enhanced.

The semiconductor memory device 1000 according to an embodiment may read or write data from or in the plurality of memory cells MC as one sense amplifier SA is connected to at least four bit lines BL, and thus, the number of sense amplifiers SA included in the semiconductor memory device 1000 may decrease. Therefore, an area used by each of the sense amplifiers SA included in the semiconductor memory device 1000 may increase, and thus, the operation reliability of the semiconductor memory device 1000 may be enhanced.

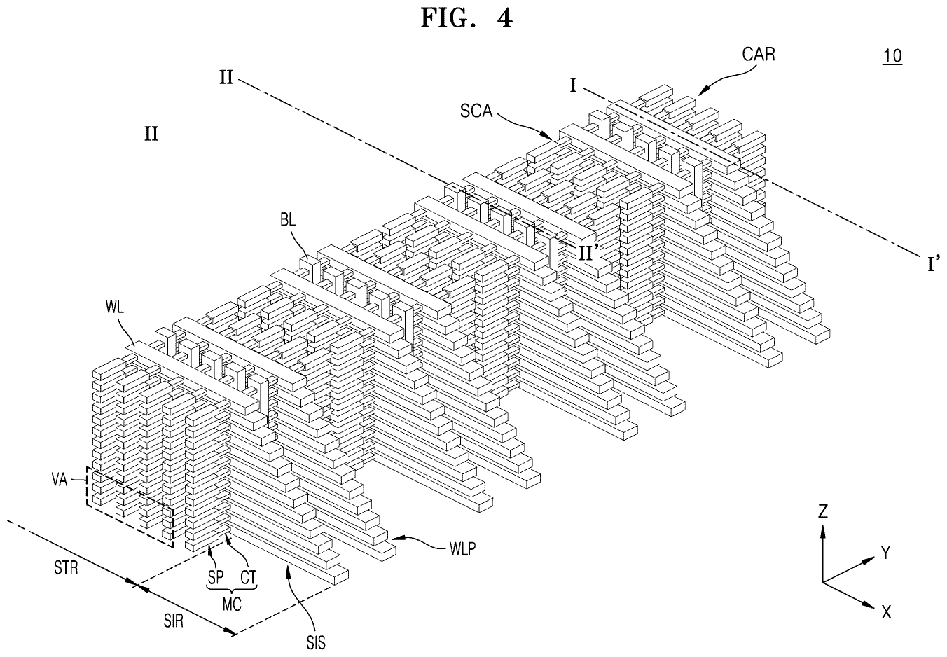

FIG. 4 is a perspective view illustrating a semiconductor memory device 10 according to embodiments.

Referring to FIG. 4, the semiconductor memory device 10 may include a cell stack region STR and a contact region SIR. The semiconductor memory device 10 may be at least a portion of the memory cell structure MCST illustrated in FIG. 3. A stack cell array structure CAR may be disposed in the cell stack region STR. In some embodiments, a stair structure SIS may be disposed in the contact region SIR. The contact region SIR may be disposed in at least one side of the cell stack region STR in a first horizontal direction (an X direction). For example, a pair of contact regions SIR may be disposed at both sides of the cell stack region STR in the first horizontal direction (the X direction). In some embodiments, the stair structure SIS may not be disposed in the contact region SIR.

The stack cell array structure CAR may include a plurality of sub cell arrays SCA. A plurality of sub cell arrays SCA included in one stack cell array structure CAR may be arranged in a second horizontal direction (a Y direction). The sub cell array SCA may include a plurality of bit lines BL, a plurality of word lines WL, and a plurality of memory cells MC. Each of the plurality of memory cells MC may include a cell transistor CT and an information storage element SP.

The plurality of word lines WL may extend in the first horizontal direction (the X direction). In the stack cell array structure CAR, the plurality of word lines WL may extend in the first horizontal direction (the X direction) and may be apart from each other in each of the second horizontal direction (the Y direction) and a vertical direction (a Z direction). Word lines WL of one sub cell array SCA may be apart from each other in a vertical direction (a Z direction).

The bit line BL may extend in the vertical direction (the Z direction) from a substrate. In the stack cell array structure CAR, the plurality of bit lines BL may extend in a vertical direction (a Z direction) and may be apart from each other in each of the first horizontal direction (the X direction) and the second horizontal direction (the Y direction). Bit lines BL of one sub cell array SCA may be apart from each other in the first horizontal direction (the X direction).

One cell transistor CT may be disposed between one word line WL and one bit line BL. The information storage element SP may be connected to the cell transistor CT. The information storage element SP may be a memory element which may store data. A gate of the cell transistor CT may be connected to the word line WL, and the bit line BL may be connected to a source region of the cell transistor CT. The information storage element SP may be connected to a drain region of the cell transistor CT.

In some embodiments, the source region and the drain region of the cell transistor CT and the information storage element SP may be arranged in the second horizontal direction (the Y direction) from a bit line BL connected to the source region of the cell transistor CT. A source region and a drain region of a cell transistor connected to each of two bit lines BL adjacent to each other in the second horizontal direction (the Y direction) and the information storage element SP may be disposed in opposite directions. For example, a source region and a drain region of a cell transistor connected to one of two bit lines BL adjacent to each other in the second horizontal direction (the Y direction) and the information storage element SP may be disposed in the second horizontal direction (the Y direction), and a source region and a drain region of a cell transistor connected to the other bit line BL and the information storage element SP may be disposed in a direction opposite to the second horizontal direction (the Y direction). For example, the plurality of bit lines BL may include a first bit line, a second bit line, a third bit line, and a fourth bit line, which are sequentially arranged adjacent to each other in the second horizontal direction (the Y direction), the memory cell MC may not be disposed between the first bit line and the second bit line, two memory cells MC may be disposed in the second horizontal direction (the Y direction) at the same vertical level, between the second bit line and the third bit line, and the memory cell MC may not be disposed between the third bit line and the fourth bit line.

Each of the plurality of word lines WL may extend in the first horizontal direction (the X direction) from the cell stack region STR to the contact region SIR disposed in the first horizontal direction (the X direction). In some embodiments, the plurality of word lines WL may have a stair structure in the contact region SIR. An extension length of each of the plurality of word lines WL in the first horizontal direction (the X direction) may decrease toward an upper side thereof from a lower side thereof in the vertical direction (the Z direction). For example, an extension length in the first horizontal direction (the X direction) of a word line WL disposed at a lower side among a plurality of word lines WL disposed apart from one another in the vertical direction (the Z direction) may be longer than an extension length in the first horizontal direction (the X direction) of a word line WL disposed at an upper side. For example, an extension length of a lowermost word line WL among word lines WL stacked in the vertical direction (the Z direction) in one sub cell array SCA may be longer than an extension length of each of the other word lines WL. An extension length of an uppermost word line WL among word lines WL stacked in the vertical direction (the Z direction) in one sub cell array SCA may be shorter than an extension length of each of the other word lines WL. A word line pad part WLP may be disposed at both ends of each of the plurality of word lines WL. A portion of another word line WL may not be disposed at an upper side of the word line pad part WLP in the vertical direction (the Z direction) in one sub cell array SCA.

One word line WL may include a word line pad part WLP in at least one end thereof in the first horizontal direction (the X direction). A plurality of word line contacts may be connected to a plurality of word line pad parts WLP included in the plurality of word lines WL. The plurality of word line pad parts WLP included in the plurality of word lines WL may be disposed not to overlap each other in the vertical direction (the Z direction). In FIG. 4, for convenience of the illustration, the illustration of the plurality of word line contacts connected to the plurality of word line pad parts WLP is omitted. The word line contact may be electrically connected to a sub word line driver. The stair structure SIS may include portions of the plurality of word lines WL, which extend from the cell stack region STR to the contact region SIR and each include the word line pad part WLP.

In some embodiments, the plurality of word lines WL may not have a stair structure in the contact region SIR. For example, the extension lengths of each of the plurality of word lines WL in the first horizontal direction (the X direction) may be substantially equal to one another. The plurality of word lines WL may include the plurality of word line pad parts WLP which are portions of the plurality of word lines WL, in the contact region SIR. The plurality of word line pad parts WLP included in the plurality of word lines WL may be disposed not to overlap each other in the vertical direction (the Z direction). The plurality of word line contacts may be connected to the plurality of word line pad parts WLP which are included in and correspond to the plurality of word lines WL. Each of at least some of the plurality of word line contacts may pass through some of the plurality of word lines WL and may be electrically connected to a corresponding word line pad part WLP.

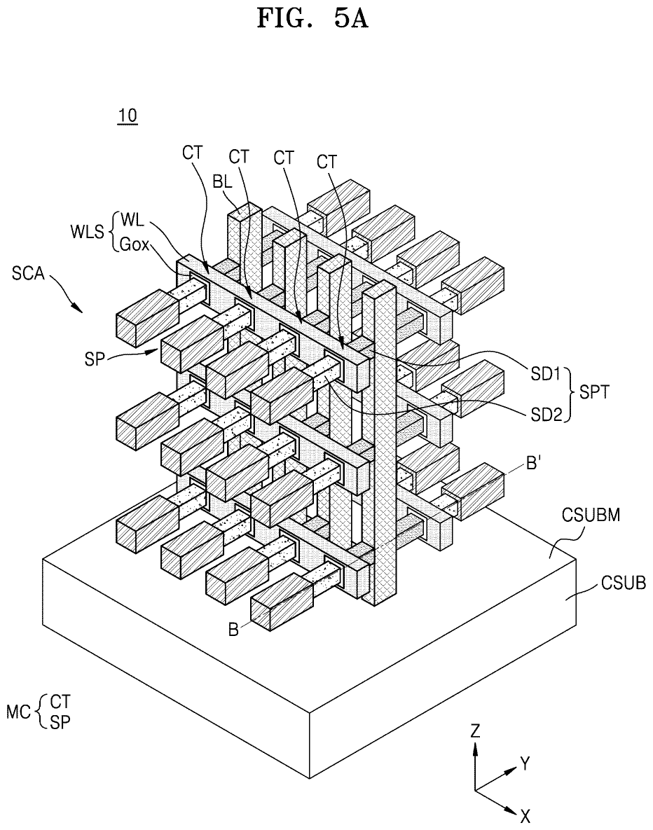

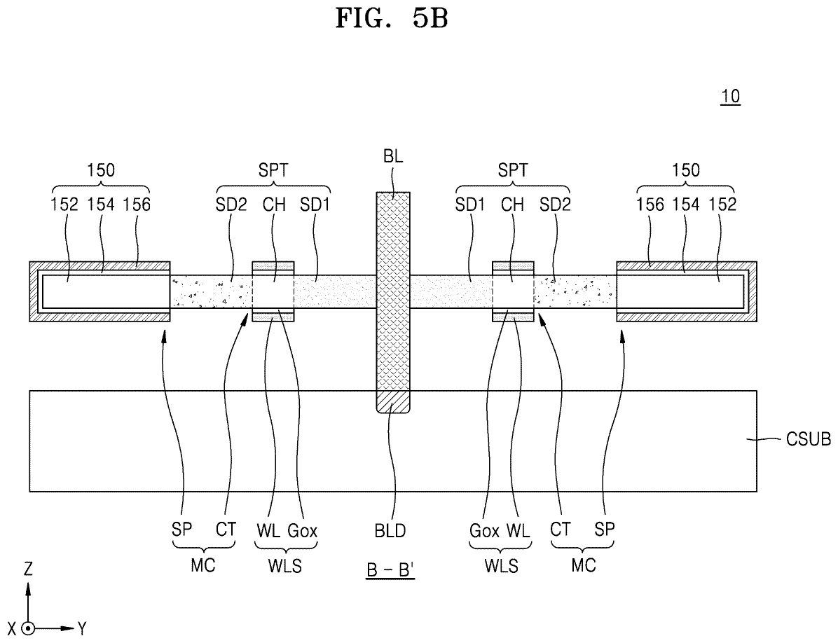

FIGS. 5A and 5B are a perspective view and a cross-sectional view illustrating a portion of a semiconductor memory device 10 according to embodiments. In detail, FIG. 5A is a perspective view illustrating the enlargement of a region VA of FIG. 4, and FIG. 5B is a cross-sectional view taken along line B-B′ of FIG. 5A.

Referring to FIGS. 5A and 5B, the semiconductor memory device 10 may include a cell substrate CSUB and a plurality of sub cell arrays SCA disposed on the cell substrate CSUB. The plurality of sub cell arrays SCA may be arranged in a second horizontal direction (a Y direction). The sub cell array SCA may include the cell substrate CSUB, a plurality of word lines WL which are apart from a main surface CSUBM of the cell substrate CSUB and extend in a first horizontal direction (an X direction) on the cell substrate CSUB, a plurality of bit lines BL which extend in a vertical direction (a Z direction) from the main surface CSUBM of the cell substrate CSUB, a plurality of cell transistors CT which are disposed between the plurality of word lines WL and the plurality of bit lines BL, and a plurality of information storage elements SP which are connected to the plurality of cell transistors CT. The plurality of cell transistors CT and the plurality of information storage elements SP may configure a plurality of memory cells MC. In some embodiments, in the semiconductor memory device 10, the cell substrate CSUB may be omitted.

The plurality of word lines WL may extend in the first horizontal direction (the X direction) on the cell substrate CSUB and may be apart from one another in each of a second horizontal direction (a Y direction) and the vertical direction (the Z direction). The plurality of bit lines BL may extend in the vertical direction (the Z direction) from the cell substrate CSUB and may be apart from one another in the first horizontal direction (the X direction). In FIG. 5A, it is illustrated that the plurality of bit lines BL are apart from one another in the first horizontal direction (the X direction) and extend in the vertical direction (the Z direction), but as illustrated in FIG. 4, the plurality of bit lines BL are apart from one another in each of the first horizontal direction (the X direction) and the second horizontal direction (the Y direction) and extend in the vertical direction (the Z direction).

One cell transistor CT may be disposed between one word line WL and one bit line BL. The information storage element SP may be connected to the cell transistor CT. The cell transistor CT and the information storage element SP may be sequentially arranged in the second horizontal direction (the Y direction) or an opposite direction of the second horizontal direction (the Y direction) from a bit line BL connected to the cell transistor CT.

The word line WL may be adjacent to a semiconductor pattern SPT. In some embodiments, the word line WL may surround at least a portion of the semiconductor pattern SPT extending in the second horizontal direction (the Y direction). For example, the word line WL may have a gate all around (GAA) type which covers an upper surface and a lower surface of a portion of the semiconductor pattern SPT and both side surfaces of the semiconductor pattern SPT in the first horizontal direction (the X direction). In some embodiments, the word line WL may have a double gate type which covers an upper surface and a lower surface of a portion of the semiconductor pattern SPT. In some embodiments, the word line WL may have a single gate type which covers one of an upper surface and a lower surface of a portion of the semiconductor pattern SPT. For example, the word line WL may cover an upper surface of a portion of the semiconductor pattern SPT. For example, the word line WL may cover a lower surface of a portion of the semiconductor pattern SPT. A gate dielectric layer Gox may be disposed between the word line WL and the semiconductor pattern SPT. The word line WL and the gate dielectric layer Gox may configure a word line structure WLS. The semiconductor pattern SPT and the word line structure WLS may configure a cell transistor CT.

The semiconductor pattern SPT may include a semiconductor material. In some embodiments, the semiconductor pattern SPT may include silicon. In some embodiments, the semiconductor pattern SPT may include a poly-crystalline semiconductor material. For example, the semiconductor pattern SPT may include single crystalline silicon (Si). In some other embodiments, the semiconductor pattern SPT may include a two-dimensional semiconductor material or an oxide semiconductor material. For example, the 2D semiconductor material may include MoS₂, WSe₂, graphene, carbon nano tube, or a combination thereof. For example, the oxide semiconductor material may include InₓGa_{y}Zn_{z}O, tin (Sn) doped InₓGa_{y}Zn_{z}O, InₓGa_{y}Si_{z}O, InₓSn_{y}Zn_{z}O, InₓZn_{y}O, tungsten (W) doped InO, InZnₓO, ZnₓSn_{y}O, ZnₓO_{y}N, ZrₓZn_{y}Sn_{z}O, yttrium (Y) doped ZnO, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof.

In the second horizontal direction (the Y direction), one end of the semiconductor pattern SPT may be connected to the bit line BL, and the other end of the semiconductor pattern SPT may be connected to the information storage element SP. The semiconductor pattern SPT may include a source region SD1, a drain region SD2, and a channel region CH disposed between the source region SD1 and the drain region SD2. The source region SD1 may be connected to the bit line BL, and the drain region SD2 may be connected to the information storage element SP. The source region SD1 may be referred to as a direct contact, and the drain region SD2 may be referred to as a buried contact.

The source region SD1, the channel region CH, and the drain region SD2 may be sequentially arranged in the second horizontal direction (the Y direction) or the opposite direction of the second horizontal direction (the Y direction) from the bit line BL. For example, two sub cell arrays SCA adjacent to each other in the second horizontal direction (the Y direction) may share bit lines BL. Source regions SD1 of cell transistors CT included in each of two sub cell arrays SCA may be connected to bit lines BL shared by the two sub cell arrays SCA. A source region SD1 and a channel region CH of a cell transistor CT and an information storage element SP in each of two sub cell arrays SCA may be arranged in opposite directions from the bit lines BL shared by the two sub cell arrays SCA. For example, a source region SD1, a channel region CH, and a drain region SD2 of a cell transistor CT and an information storage element SP in one sub cell array SCA connected to one bit line BL shared by two sub cell arrays SCA may be sequentially arranged in the second horizontal direction (the Y direction), and a source region SD1, a channel region CH, and a drain region SD2 of a cell transistor CT and an information storage element SP in the other sub cell array SCA may be arranged in a direction opposite to the second horizontal direction (the Y direction). For example, two memory cells MC may be arranged in the second horizontal direction (the Y direction) at the same vertical level, between a pair of bit lines BL sequentially arranged adjacent to each other in the second horizontal direction (the Y direction) among the plurality of bit lines BL.

Partial portions of a semiconductor pattern SPT and a word line WL corresponding to each other may overlap each other in the vertical direction (the Z direction). In some embodiments, the semiconductor pattern SPT may pass through the word line WL and may extend in the second horizontal direction (the Y direction). The channel region CH may include at least a portion of a portion, overlapping the word line WL in the vertical direction (the Z direction), of the semiconductor pattern SPT. In some embodiments, the channel region CH may include at least a portion of a portion, passing through the word line WL, of the semiconductor pattern SPT. For example, the channel region CH may be a portion, overlapping the word line WL in the vertical direction (the Z direction), of the semiconductor pattern SPT. In some embodiments, the channel region CH may be a portion, passing through the word line WL, of the semiconductor pattern SPT. A length of the channel region CH in the second horizontal direction (the Y direction) may be the same as that of the word line WL in the second horizontal direction (the Y direction). A length of the source region SD1 in the second horizontal direction (the Y direction) may be the same as an interval between the word line WL and the bit line BL in the second horizontal direction (the Y direction).

In some embodiments, a first impurity may be doped in the source region SD1 and the drain region SD2 of the semiconductor pattern SPT. In some embodiments, a second impurity which differs from the first impurity may be doped in the channel region CH. For example, the first impurity may allow each of the source region SD1 and the drain region SD2 to have a first conductive type, and the second impurity may allow the channel region CH to have a second conductive type which differs from the first conductive type. In some embodiments, the first conductive type may be n type, and the second conductive type may be p type, but the inventive concept is not limited thereto. For example, the first conductive type may be p type, and the second conductive type may be n type, but the inventive concept is not limited thereto. When the first conductive type is n type, the first impurity may be phosphorus (P), arsenic (As), or antimony (Sb), and when the second conductive type is p type, the second impurity may be boron (B), aluminum (Al), gallium (Ga), or indium (In). For example, phosphorus (P) may be doped in the source region SD1 and the drain region SD2 of the semiconductor pattern SPT. In some other embodiments, each of the source region SD1, the channel region CH, and the drain region SD1 of the semiconductor pattern SPT may include a semiconductor material which entirely has the same impurity concentration, or may include an intrinsic semiconductor material into which impurities are not entirely implanted. For example, the semiconductor pattern SPT may have a junction-less structure.

The word line WL may surround a portion of the semiconductor pattern SPT with the gate dielectric layer Gox therebetween. For example, the gate dielectric layer Gox may cover an upper surface and a lower surface of a portion of the semiconductor pattern SPT and both side surfaces of the semiconductor pattern SPT in the first horizontal direction (the X direction), and the word line WL may cover the gate dielectric layer Gox covering the upper surface and the lower surface of the portion of the semiconductor pattern SPT and the both side surfaces of the semiconductor pattern SPT in the first horizontal direction (the X direction). The word line WL may include a conductive barrier layer covering the gate dielectric layer Gox and a conductive filling layer covering the conductive barrier layer. The conductive barrier layer may include, for example, metal, conductive metal nitride, conductive metal silicide, or a combination thereof. For example, the conductive barrier layer may include titanium nitride (TiN). The conductive filling layer may include, for example, doped Si, ruthenium (Ru), ruthenium oxide (RuO), platinum (Pt), platinum oxide (PtO), iridium (Ir), iridium oxide (IrO), SRO(SrRuO), BSRO((Ba,Sr)RuO), CRO(CaRuO), barium ruthenium oxide (BaRuO), La(Sr,Co)O, titanium (Ti), titanium nitride (TiN), tungsten (W), tungsten nitride (WN), tantalum (Ta), tantalum nitride (TaN), titanium aluminum nitride (TiAlN), titanium silicon nitride (TiSiN), tantalum aluminum nitride (TaAlN), tantalum silicon nitride (TaSiN), or a combination thereof. In some embodiments, the conductive filling layer may include W. The gate dielectric layer Gox may include at least one material selected from among silicon oxide, a high-k dielectric material having a dielectric constant which is higher than that of silicon oxide, and a ferroelectric material. In some embodiments, the gate dielectric layer Gox may have a stack structure of a first dielectric layer including silicon oxide and a second dielectric layer including at least one of a high-k dielectric material and a ferroelectric material. For example, the high-k dielectric material and the ferroelectric material may include at least one material selected from among hafnium oxide (HfO), hafnium silicate (HfSiO), hafnium oxide nitride (HfON), hafnium silicon oxide nitride (HfSiON), lanthanum oxide (LaO), lanthanum aluminum oxide (LaAlO), zirconium oxide (ZrO), zirconium silicon oxide (ZrSiO), zirconium oxide nitride (ZrON), zirconium silicon oxide nitride (ZrSiON), tantalum oxide (TaO), titanium oxide (TiO), barium strontium titanium oxide (BaSrTiO), barium titanium oxide (BaTiO), lead zirconate titanate (PZT), strontium tantalate bismuth (STB), bismuth iron oxide (BFO), strontium titanium oxide (SrTiO), yttrium oxide (YO), aluminum oxide (AlO), and lead scandium tantalum oxide (PbScTaO).

The bit line BL may include metal. For example, the bit line BL may include metal such as Ti, Ta, molybdenum (Mo), Ru, W, cobalt (Co), Al, or nickel (Ni), conductive metal nitride such as TiN, TaN, WN, RuTiN, TiSiN, WSiN, or TaSiN, metal silicide such as TiSi, WSi, TaSi, CoSi, or NiSi, or a combination thereof, but is not limited thereto. In some embodiments, the bit line BL may include a conductive barrier layer contacting the source region SD1 and a conductive filling layer covering the conductive barrier layer. The conductive barrier layer may include, for example, metal, conductive metal nitride, conductive metal silicide, or a combination thereof. For example, the conductive barrier layer may include TiN. The conductive filling layer may include, for example, doped Si, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or a combination thereof. In some embodiments, the conductive filling layer may include W.

The bit line BL may be apart from the cell substrate CSUB. In some embodiments, a separation insulation layer BLD may be disposed between the cell substrate CSUB and the bit line BL. The bit line BL may be disposed on the separation insulation layer BLD. The separation insulation layer BLD may electrically insulate the cell substrate CSUB from the bit line BL. At least a portion of the separation insulation layer BLD may be buried in the cell substrate CSUB. In some embodiments, the separation insulation layer BLD may include an insulating material including impurities.

In some embodiments, the information storage element SP may be a capacitor structure 150 which includes a first electrode 152, a second electrode 156, and a capacitor dielectric layer 154 disposed between the first electrode 152 and the second electrode 156. The capacitor structure 150 may include the first electrode 152 which is connected to the drain region SD2 of the semiconductor pattern SPT and extends in the second horizontal direction (the Y direction), the capacitor dielectric layer 154 covering the first electrode 152, and the second electrode 156 covering the capacitor dielectric layer 154. The second electrode 156 may be connected to a ground wiring PP illustrated in FIG. 1, or may be a portion of the ground wiring PP. The first electrode 152 and the second electrode 156 may be respectively referred to as a lower electrode and an upper electrode. The capacitor dielectric layer 154 may be disposed between the first electrode 152 and the second electrode 156.

The first electrode 152 may include metal, conductive metal nitride, conductive metal silicide, or a combination thereof. In some embodiments, the first electrode 152 may include a refractory metal layer such as cobalt, Ti, Ni, W, and Mo. For example, the first electrode 152 may include metal nitrides such as titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), and tungsten nitride (WN).

The capacitor dielectric layer 154 may include at least one material selected from among silicon oxide, a high-k dielectric material having a dielectric constant which is higher than that of silicon oxide, and a ferroelectric material. For example, the capacitor dielectric layer 154 may include at least one of metal oxide and a dielectric material of a perovskite structure. In some embodiments, the capacitor dielectric layer 154 may include at least one material selected from among HfO, HfSiO, HfON, HfSiON, LaO, LaAlO, ZrO, ZrSiO, ZrON, ZrSiON, TaO, TiO, BaSrTiO, BaTiO, PZT, STB, BFO, SrTiO, YO, AlO, and PbScTaO.

The second electrode 156 may include, for example, doped Si, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or a combination thereof. In some embodiments, the second electrode 156 may include W. In FIGS. 3 and 4, it is illustrated that a plurality of information storage elements SP are apart from one another, but the inventive concept is not limited thereto. In some embodiments, when the plurality of information storage elements SP are a plurality of capacitor structures 150, a plurality of second electrodes 156 of the plurality of capacitor structures 150 included in the sub cell array SCA may be connected to each other to configure one body. In some embodiments, in the case where the plurality of information storage elements SP are the plurality of capacitor structures 150, when a plurality of capacitor structures 150 included in each of a pair of sub cell arrays SCA adjacent to each other in the second horizontal direction (the Y direction) face each other and are adjacent to each other, a plurality of second electrodes 156 of the plurality of capacitor structures 150 included in each of the pair of sub cell arrays SCA may be connected to each other to configure one body.

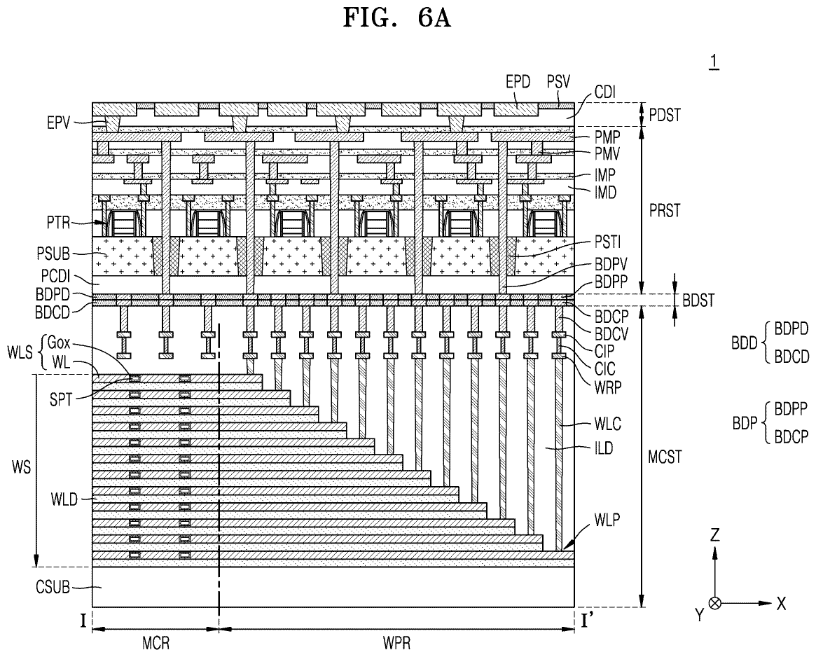

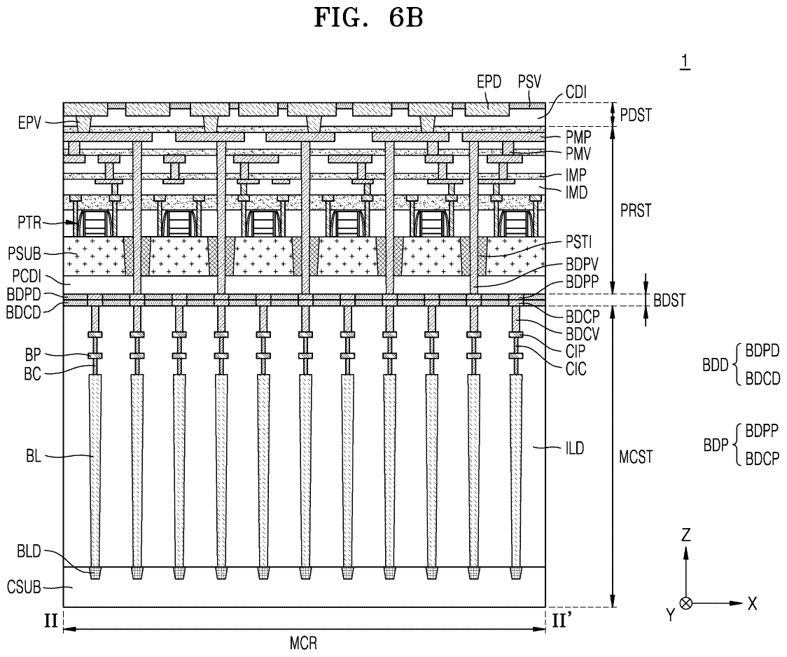

FIGS. 6A and 6B are cross-sectional views illustrating a semiconductor memory device 1 according to embodiments.

In detail, FIG. 6A is a cross-sectional view taken along a position corresponding to line I-I′ of FIG. 4, and FIG. 6B is a cross-sectional view taken along a position corresponding to line II-II′ of FIG. 4.

Referring to FIGS. 6A and 6B, the semiconductor memory device 1 may include a memory cell region MCR and a pad region WPR, which are disposed in a first horizontal direction (an X direction). The semiconductor memory device 1 may include a memory cell structure MCST, a peripheral circuit structure PRST on the memory cell structure MCST, a bonding structure BDST between the memory cell structure MCST and the peripheral circuit structure PRST, and an external connection pad structure PDST on the peripheral circuit structure PRST. Each of the memory cell structure MCST, the bonding structure BDST, the peripheral circuit structure PRST, and the external connection pad structure PDST may be an arbitrary division based on convenience of description and a functional difference, and thus, a division between structures may not be clear.

The memory cell structure MCST may include a plurality of word lines WL which extend in the first horizontal direction (the X direction) on a cell substrate CSUB and are apart from one another in each of a second horizontal direction (a Y direction) and a vertical direction (a Z direction). The plurality of word lines WL may configure a word line stack WS. A plurality of insulation layers WLD may be disposed between word lines WL aligned in the vertical direction (the Z direction) and/or between the cell substrate CSUB and the word line WL. For example, the plurality of insulation layers WLD may include oxide, but are not limited thereto. The plurality of word lines WL may include a plurality of word line pad parts WLP disposed in the pad region WPR. The plurality of word line pad parts WLP included in the plurality of word lines WL may not overlap each other in the vertical direction (the Z direction). A plurality of word line contacts WLC may be connected to the plurality of word line pad parts WLP. The plurality of word line contacts WLC may be connected to the word line pad part WLP and may extend in the vertical direction (the Z direction) from the connected word line pad part WLP. The plurality of word line contacts WLC may have a tapered shape which distances from the word line pad part WLP, extends in the vertical direction (the Z direction), and narrows in horizontal width. A plurality of routing pads WRP may be connected to upper ends of the plurality of word line contacts WLC.

The memory cell structure MCST may include a plurality of bit lines BL which extend in the vertical direction (the Z direction) on the cell substrate CSUB and are apart from one another in each of the first horizontal direction (the X direction) and the second horizontal direction (the Y direction). The plurality of bit lines BL may configure a column in the first horizontal direction (the X direction) and may include bit line columns which include bit lines BL disposed apart from one another, and the bit line columns may be arranged apart from one another in the second horizontal direction (the Y direction). Each of the bit line columns may be disposed along an extension line which extends in the first horizontal direction (the X direction) along a region between the two word lines WL adjacent to each other in the second horizontal direction (the Y direction) at the same vertical level. In some embodiments, one bit line column and a pair of word lines WL may be one-dimensionally and repeatedly arranged in the second horizontal direction (the Y direction). The bit line BL may be apart from the cell substrate CSUB. In some embodiments, a separation insulation layer BLD may be disposed between the cell substrate CSUB and the bit line BL. Each of the plurality of bit lines BL may have a tapered shape which extends and has a horizontal width increasing from a lower side thereof to an upper side thereof. A plurality of bit line contacts BC may be connected to upper ends of the plurality of bit lines BL. A plurality of bit line connection patterns BP may be connected to upper ends of the plurality of bit line contacts BC.

The memory cell structure MCST may include a plurality of memory cells MC each including a cell transistor CT and an information storage element SP. The cell transistor CT may include a semiconductor pattern SPT. The plurality of memory cells MC may be configured by the plurality of word lines WL, the plurality of bit lines BL, a plurality of semiconductor patterns SPT, and a plurality of information storage elements SP. In some embodiments, the plurality of semiconductor patterns SPT may extend in the second horizontal direction (the Y direction) and may be arranged apart from one another to configure a column in the first horizontal direction (the X direction) and the vertical direction (the Z direction). The cell transistor CT may be disposed between the word line WL and the bit line BL. The information storage element SP may be connected to the cell transistor CT. The information storage element SP may be a memory element which may store data. A gate of the cell transistor CT may be connected to the word line WL, a source region of the cell transistor CT may be connected to the bit line BL, and the information storage element SP may be connected to a drain region of the cell transistor CT.

The word line WL may be adjacent to a semiconductor pattern SPT. In some embodiments, the word line WL may surround the semiconductor pattern SPT. A gate dielectric layer Gox may be disposed between the word line WL and the semiconductor pattern SPT. The word line WL and the gate dielectric layer Gox may configure a word line structure WLS. The semiconductor pattern SPT and the word line structure WLS may configure a cell transistor CT.

A plurality of cell connection contacts CIC and a plurality of cell connection patterns CIP may be connected onto a plurality of bit line connection patterns BP and a plurality of routing pads WRP. The plurality of cell connection contacts CIC may connect the plurality of bit line connection patterns BP and/or the plurality of routing pads WRP to the plurality of cell connection patterns CIP. An interlayer insulation layer ILD may surround the plurality of word line WL, the plurality of word line contacts WLC, the plurality of routing pads WRP, the plurality of bit lines BL, the plurality of bit line contacts BC, the plurality of bit line connection patterns BP, the plurality of cell connection contacts CIC, and the plurality of cell connection patterns CIP. The interlayer insulation layer ILD may include oxide, but is not limited thereto.

The peripheral circuit structure PRST may include a peripheral circuit substrate PSUB and a plurality of peripheral circuit transistors PTR. The plurality of peripheral circuit transistors PTR may be disposed on upper surfaces of portions of the peripheral circuit substrate PSUB defined by a device isolation insulation layer PSTI. The device isolation insulation layer PSTI may be buried in the peripheral circuit substrate PSUB. The plurality of peripheral circuit transistors PTR may be configured to transfer a signal and/or power to the plurality of memory cells MC included in the memory cell structure MCST. For example, the plurality of peripheral circuit transistors PTR may configure various circuits such as a command decoder, a control logic, an address buffer, a row decoder, a column decoder, a sense amplifier, a multiplexer, and a data I/O circuit. For example, some of the plurality of peripheral circuit transistors PTR may configure the sense amplifier SA and the multiplexer MX each illustrated in FIG. 3. In FIGS. 6A and 6B, it is illustrated that the peripheral circuit transistor PTR is a planar transistor, but the inventive concept is not limited thereto. For example, the peripheral circuit transistor PTR may be a Fin field effect transistor (FinFET) or a vertical gate transistor.

The peripheral circuit structure PRST may further include a plurality of peripheral circuit connection patterns PMP on the peripheral circuit substrate PSUB, a plurality of peripheral circuit connection vias PMV connected to the plurality of peripheral circuit connection patterns PMP, and a peripheral circuit wiring insulation layer IMD which surrounds the plurality of peripheral circuit connection patterns PMP and the plurality of peripheral circuit connection vias PMV and covers the peripheral circuit substrate PSUB. When the plurality of peripheral circuit connection patterns PMP are buried in the peripheral circuit wiring insulation layer IMD, the peripheral circuit structure PRST may further include a peripheral circuit wiring protection layer IMP which covers the plurality of peripheral circuit connection patterns PMP and the peripheral circuit wiring insulation layer IMD. The peripheral circuit wiring insulation layer IMD may include oxide, and the peripheral circuit wiring protection layer IMP may include nitride. A peripheral circuit connection via PMV disposed at the lowermost end among the plurality of peripheral circuit connection vias PMV may be connected to the peripheral circuit substrate PSUB and/or the plurality of peripheral circuit transistors PTR. In some embodiments, the peripheral circuit structure PRST may further include a peripheral circuit cover insulation layer PCDI which covers a lower surface of the peripheral circuit substrate PSUB. In some embodiments, the peripheral circuit cover insulation layer PCDI may be omitted.

The bonding structure BDST may be disposed between the memory cell structure MCST and the peripheral circuit structure PRST. The bonding structure BDST may include a plurality of peripheral circuit bonding pads BDPP disposed under the peripheral circuit structure PRST, a peripheral circuit bonding insulation layer BDPD which is disposed under the peripheral circuit structure PRST and surrounds the plurality of peripheral circuit bonding pads BDPP, a plurality of cell bonding pads BDCP disposed on the memory cell structure MCST, and a cell bonding insulation layer BDCD which is disposed on the memory cell structure MCST and surrounds the plurality of cell bonding pads BDCP. Lower surfaces of the plurality of peripheral circuit bonding pads BDPP may be coplanar with a lower surface of the peripheral circuit bonding insulation layer BDPD. Upper surfaces of the plurality of peripheral circuit bonding pads BDPP may be coplanar with an upper surface of the peripheral circuit bonding insulation layer BDPD.

The memory cell structure MCST may be bonded onto the peripheral circuit structure PRST through the plurality of cell bonding pads BDCP, the plurality of peripheral circuit bonding pads BDPP, the plurality of cell bonding insulating layers BDCD, and the peripheral circuit bonding insulation layer BDPD, which are included in the bonding structure BDST. For example, the cell bonding insulation layer BDCD and the peripheral circuit bonding insulation layer BDPD may be bonded to each other to form a covalent bond, and the cell bonding pad BDCP and the peripheral circuit bonding pad BDPP corresponding to each other may face each other and may expand based on heat to be bonded to each other and may be bonded to each other through diffusion bonding to configure one body, based on diffusion of metal atoms included therein. The cell bonding insulation layer BDCD and the peripheral circuit bonding insulation layer BDPD may form a covalent bond and may be bonded to each other to configure a bonding insulation layer BDD. The cell bonding pad BDCP and the peripheral circuit bonding pad BDPP corresponding to each other may configure a bonding pad BDP.

The memory cell structure MCST and the peripheral circuit structure PRST may be bonded to each other by a hybrid bonding process. The cell bonding pad BDCP and the peripheral circuit bonding pad BDPP may include a material including copper (Cu). The cell bonding insulation layer BDCD and the peripheral circuit bonding insulation layer BDPD may include silicon oxide or silicon carbonitride (SiCN).

The bonding structure BDST may further include a plurality of cell bonding vias BDCV and a plurality of peripheral circuit bonding vias BDPV. The cell bonding via BDCV may extend from a corresponding cell bonding pad BDCP to the memory cell structure MCST in the vertical direction (the Z direction). The cell bonding via BDCV may connect the cell bonding pad BDCP to the cell connection pattern CIP. The cell bonding via BDCV may pass through the interlayer insulation layer IDL and may connect the cell bonding pad BDCP to the cell connection pattern CIP. The peripheral circuit bonding via BDPV may extend from a corresponding peripheral circuit bonding pad BDPP to the peripheral circuit structure PRST in the vertical direction (the Z direction). The peripheral circuit bonding via BDPV may connect the peripheral circuit bonding pad BDPP to the peripheral circuit connection pattern PMP. The peripheral circuit bonding via BDPV may pass through the wiring insulation layer IMD, the peripheral circuit wiring protection layer IMP, and/or the device isolation insulation layer PSTI and may connect the peripheral circuit bonding pad BDPP to the peripheral circuit connection pattern PMP. The peripheral circuit bonding via BDPV, the bonding pad BDP, and the cell bonding via BDCV may configure the circuit cell connection structure PCIT illustrated in FIG. 3. The peripheral circuit bonding via BDPV, the bonding pad BDP, and the cell bonding via BDCV may electrically connect the plurality of word lines WL and the plurality of bit lines BL to the plurality of peripheral circuit transistors PTR.

The external connection pad structure PDST may include a plurality of external connection pads EPD on the peripheral circuit structure PRST, a plurality of external connection vias EPV connecting the plurality of external connection pads EPD to the plurality of peripheral circuit connection patterns PMP, and a cover insulation layer CDI which surrounds the plurality of external connection pads EPD and the plurality of external connection vias EPV. In some embodiments, a protection insulation layer PSV may be disposed on the cover insulation layer CDI. At least partial portions of upper surfaces of the plurality of external connection pads EPD may be exposed without being covered by the protection insulation layer PSV. The cover insulation layer CDI may include oxide, and the protection insulation layer PSV may include nitride.

In FIGS. 6A and 6B, the semiconductor memory device 1 is illustrated as having a PoC structure where the memory cell structure MCST, the bonding structure BDST, the peripheral circuit structure PRST, and the external connection pad structure PDST are sequentially stacked, and thus, the peripheral circuit structure PRST is disposed on the memory cell structure MCST, but this may be an embodiment and the inventive concept is not limited thereto. In some embodiments, the semiconductor memory device 1 is illustrated as having a PoC structure where the peripheral circuit structure PRST, the bonding structure BDST, the memory cell structure MCST, and the external connection pad structure PDST are sequentially stacked, and thus, the memory cell structure MCST is disposed on the peripheral circuit structure PRST. Alternatively, the semiconductor memory device 1 may be modified so that a top and a bottom of the memory cell structure MCST are reversed, or a top and a bottom of the peripheral circuit structure PRST are reversed, or the cell substrate CSUB is omitted, or the peripheral circuit substrate PSUB is omitted.

The semiconductor memory device 1 according to an embodiment may include a memory cell structure MCST and a peripheral circuit structure PRST, which are stacked in a vertical direction (a Z direction), and thus, the number of memory cells which may be one-dimensionally disposed in the same area may increase. Moreover, the sense amplifier SA and the multiplexer MX each illustrated in FIG. 3 may be configured by some of the plurality of peripheral circuit transistors PTR included in the peripheral circuit structure PRST, and thus, the degree of integration and operation reliability of the semiconductor memory device 1 may be enhanced.

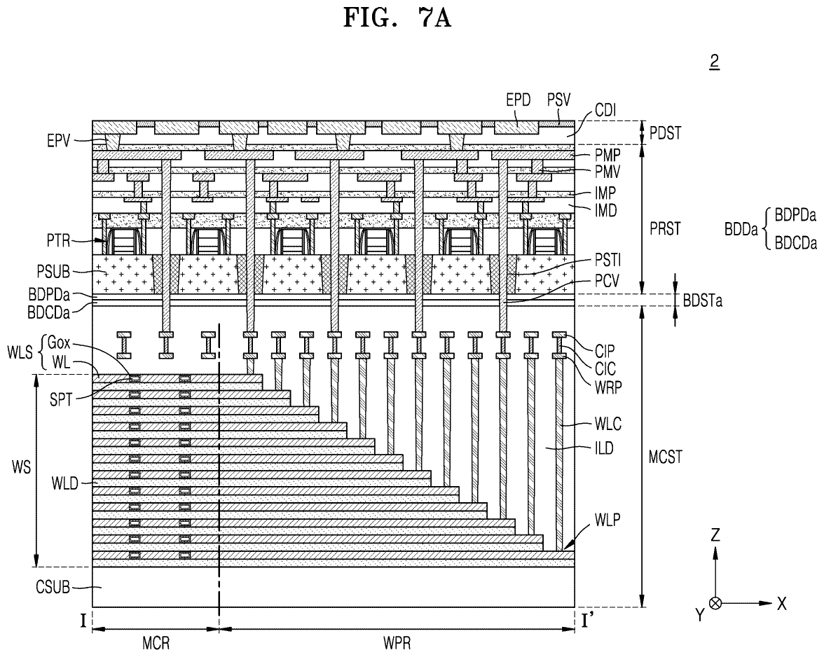

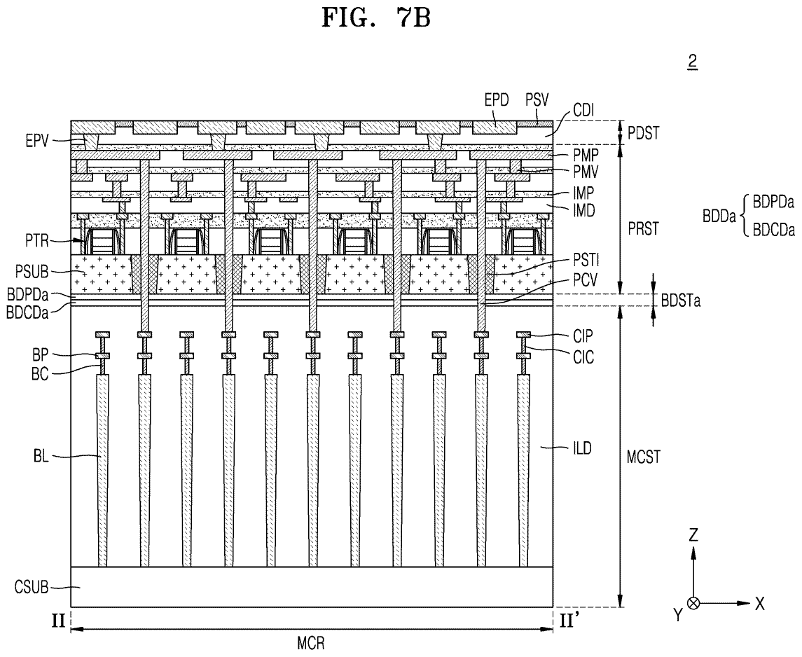

FIGS. 7A and 7B are cross-sectional views illustrating a semiconductor memory device 2 according to embodiments.

Referring to FIGS. 7A and 7B, the semiconductor memory device 2 may include a memory cell region MCR and a pad region WPR, which are disposed in a first horizontal direction (an X direction). The semiconductor memory device 2 may include a memory cell structure MCST, a peripheral circuit structure PRST on the memory cell structure MCST, a bonding structure BDSTa between the memory cell structure MCST and the peripheral circuit structure PRST, and an external connection pad structure PDST on the peripheral circuit structure PRST. The memory cell structure MCST, the peripheral circuit structure PRST, and the external connection pad structure PDST may be substantially the same as the memory cell structure MCST, the peripheral circuit structure PRST, and the external connection pad structure PDST each illustrated in FIGS. 6A and 6B, and thus, their repeated descriptions are omitted.

The bonding structure BDSTa may be disposed between the memory cell structure MCST and the peripheral circuit structure PRST. The bonding structure BDSTa may include a peripheral circuit bonding insulation layer BDPDa disposed under the peripheral circuit structure PRST and a cell bonding insulation layer BDCDa disposed on the memory cell structure MCST. The memory cell structure MCST may be bonded onto the peripheral circuit structure PRST through the cell bonding insulation layer BDCDa and the peripheral circuit bonding insulation layer BDPDa each included in the bonding structure BDSTa. For example, the cell bonding insulation layer BDCDa and the peripheral circuit bonding insulation layer BDPDa may be bonded to each other to form a covalent bond. The cell bonding insulation layer BDCDa and the peripheral circuit bonding insulation layer BDPDa may form a covalent bond and may be bonded to each other to configure a bonding insulation layer BDDa. The memory cell structure MCST and the peripheral circuit structure PRST may be bonded to each other by a direct bonding process. The cell bonding insulation layer BDCDa and the peripheral circuit bonding insulation layer BDPDa may include silicon oxide or SiCN.

The bonding structure BDSTa may further include a plurality of circuit cell connection vias PCV. The circuit cell connection via PCV may connect the peripheral circuit connection pattern PMP to the cell connection pattern CIP. The circuit cell connection via PCV may pass through the bonding insulation layer BDDa, the wiring insulation layer IMD, the peripheral circuit wiring protection layer IMP, and/or the device isolation insulation layer PSTI and may connect the peripheral circuit connection pattern PMP to the cell connection pattern CIP. For example, the circuit cell connection via PCV may extend from the bonding structure BDSTa to each of the memory cell structure MCST and the peripheral circuit structure PRST in a vertical direction (a Z direction). The circuit cell connection via PCV may have a tapered shape which extends and has a horizontal width narrowing from the peripheral circuit structure PRST to the memory cell structure MCST. For example, the circuit cell connection via PCV may have a tapered shape which extends and has a horizontal width narrowing from the peripheral circuit connection pattern PMP to the cell connection pattern CIP.

The circuit cell connection via PCV may configure the circuit cell connection structure PCIT illustrated in FIG. 3. A plurality of circuit cell connection vias PCV may electrically connect a plurality of word lines WL and a plurality of bit lines BL to a plurality of peripheral circuit transistors PTR.

In FIGS. 7A and 7B, the semiconductor memory device 2 is illustrated as having a PoC structure where the memory cell structure MCST, the bonding structure BDSTa, the peripheral circuit structure PRST, and the external connection pad structure PDST are sequentially stacked, and thus, the peripheral circuit structure PRST is disposed on the memory cell structure MCST, but this may be an embodiment and the inventive concept is not limited thereto. In some embodiments, the semiconductor memory device 2 is illustrated as having a PoC structure where the peripheral circuit structure PRST, the bonding structure BDSTa, the memory cell structure MCST, and the external connection pad structure PDST are sequentially stacked, and thus, the memory cell structure MCST is disposed on the peripheral circuit structure PRST. Alternatively, the semiconductor memory device 2 may be modified so that a top and a bottom of the memory cell structure MCST are reversed, or a top and a bottom of the peripheral circuit structure PRST are reversed, or the cell substrate CSUB is omitted, or the peripheral circuit substrate PSUB is omitted.

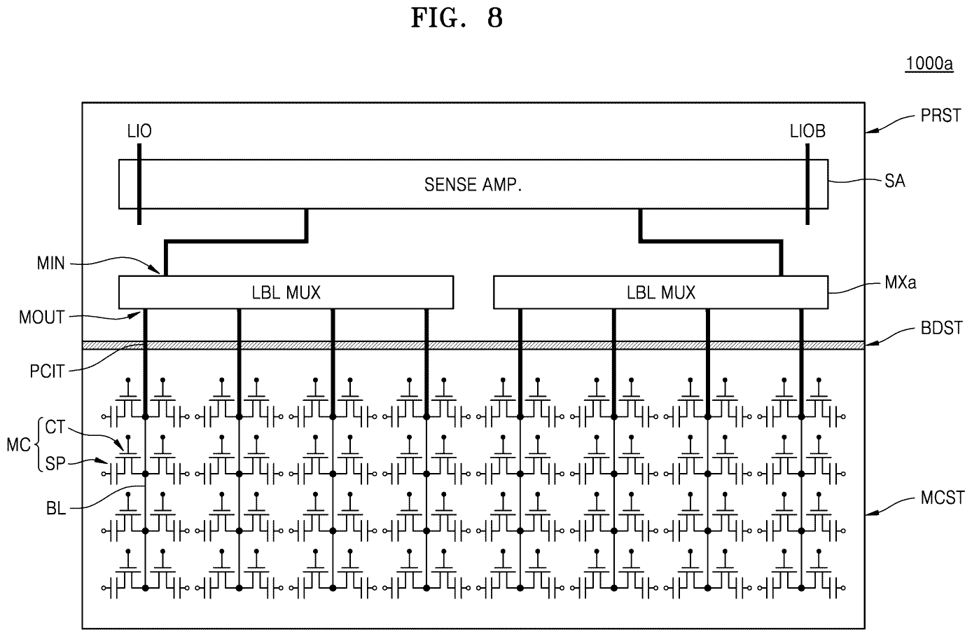

FIG. 8 is a diagram for describing a semiconductor memory device 1000a according to embodiments.

Referring to FIG. 8, the semiconductor memory device 1000a may include a memory cell structure MCST and a peripheral circuit structure PRST, which are stacked in a vertical direction (a Z direction). A bonding structure BDST may be disposed between the memory cell structure MCST and the peripheral circuit structure PRST.

The memory cell structure MCST and the peripheral circuit structure PRST may be electrically connected to each other by a circuit cell connection structure PCIT. Each of a plurality of circuit cell connection structures PCIT may pass through the bonding structure BDST and may extend into each of the memory cell structure MCST and the peripheral circuit structure PRST.

The peripheral circuit structure PRST may include a plurality of peripheral circuit transistors. The plurality of peripheral circuit transistors may be configured to transfer a signal and/or power to a plurality of memory cells included in the memory cell structure MCST. For example, the plurality of peripheral circuit transistors may configure various circuits such as a command decoder, a control logic, an address buffer, a row decoder, a column decoder, a sense amplifier SA, a multiplexer MXa, and a data I/O circuit. In FIG. 8, the sense amplifier SA and the multiplexer MXa of the various circuits configured by the plurality of peripheral circuit transistors are illustrated.

A local I/O line LIO and a local I/O line bar LIOB may be connected to the sense amplifier SA. A sense amplifier SA may be electrically connected to two bit lines BL among a plurality of bit lines BL. The multiplexer MXa may be disposed between the sense amplifier SA and the bit line BL. Two multiplexers MXa may be connected to one sense amplifier SA. One sense amplifier SA may be electrically connected to a bit line BL selected through two multiplexers MXa and the bit line BL to which the reference voltage has been supplied.

The multiplexer MXa may include one sense amplifier connection terminal MIN and four or more bit line connection terminals MOUT. The sense amplifier connection terminal MIN of the multiplexer MXa may be connected to the sense amplifier SA, and the bit line connection terminal MOUT of the multiplexer MXa may be connected to the bit line BL. The bit line connection terminal MOUT of the multiplexer MXa and the bit line BL may be connected to each other through the circuit cell connection structure PCIT. The multiplexer MXa may be a 4*1 multiplexer, an 8*1 multiplexer, a 10*1 multiplexer, a 12*1 multiplexer, a 14*1 multiplexer, or a 16*1 multiplexer, and for example, may include four or more bit line connection terminals MOUT. For example, when the multiplexer MXa is a 4*1 multiplexer, the multiplexer MXa may include four bit line connection terminals MOUT and may be connected to four bit lines BL, and moreover, may be electrically connected to one bit line BL selected from among the four bit lines BL. Therefore, the sense amplifier SA may be connected to eight or more bit lines BL through two multiplexers MX and may be electrically connected to two bit lines BL which are selected by the two multiplexers MXa from among the eight or more bit lines BL. One of two bit lines BL electrically connected to the sense amplifier SA may be one bit line BL which is selected for reading or writing data, and the other bit line BL may be a bit line BL to which the reference voltage has been supplied.

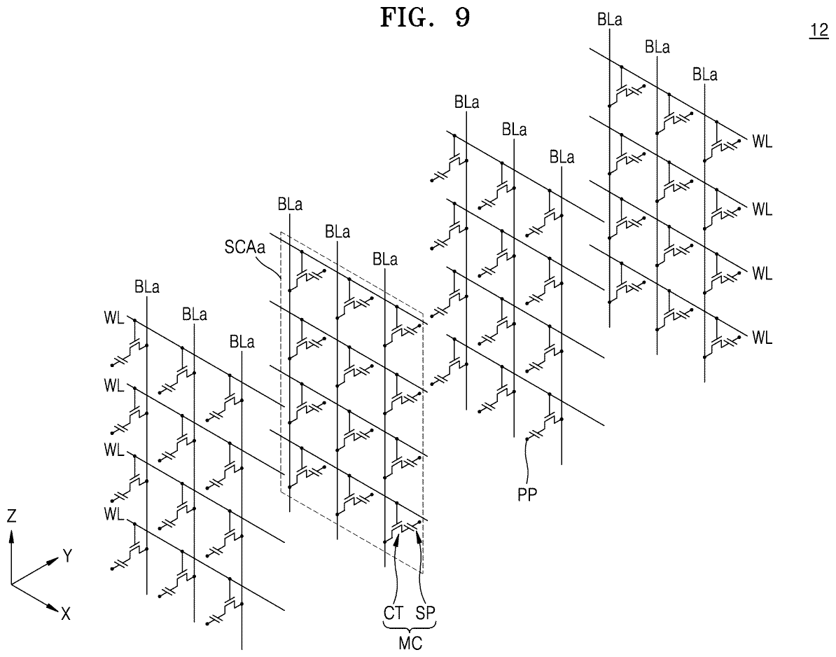

FIG. 9 is an equivalent circuit diagram illustrating a memory cell array of a semiconductor memory device 12 according to embodiments.

Referring to FIG. 9, the memory cell array of the semiconductor memory device 12 according to embodiments may include a plurality of sub cell arrays SCAa. The sub cell array SCAa may include a plurality of bit lines BLa, a plurality of word lines WL, and a plurality of memory cells MC. Each of the plurality of memory cells MC may include a cell transistor CT and an information storage element SP. One cell transistor CT may be disposed between one word line WL and one bit line BLa. The plurality of sub cell arrays SCAa may be arranged in a second horizontal direction (a Y direction).

The plurality of word lines WL may extend in the first horizontal direction (the X direction). Word lines WL of one sub cell array SCAa may be apart from each other in a vertical direction (a Z direction). The bit line BLa may extend in the vertical direction (the Z direction). Bit lines BLa of one sub cell array SCAa may be apart from each other in the first horizontal direction (the X direction). Two sub cell arrays SCAa adjacent to each other in the second horizontal direction (the Y direction) may not share bit lines BLa.

A gate of the cell transistor CT may be connected to the word line WL, and the bit line BLa may be connected to a source region of the cell transistor CT. The information storage element SP may be connected to a drain region of the cell transistor CT.

In some embodiments, the source region and the drain region of the cell transistor CT and the information storage element SP may be arranged in the second horizontal direction (the Y direction) or a direction opposite to the second horizontal direction (the Y direction) from a bit line BLa connected to the source region of the cell transistor CT. A source region and a drain region of a cell transistor CT connected to one of two bit lines BLa adjacent to each other in the second horizontal direction (the Y direction), one information storage element SP, a source region and a drain region of a cell transistor CT connected to the other bit line BLa, and another information storage element SP may be sequentially arranged in opposite directions. For example, a source region and a drain region of a cell transistor connected to one of two bit lines BLa adjacent to each other in the second horizontal direction (the Y direction) and an information storage element SP may be arranged in the second horizontal direction (the Y direction), and a source region and a drain region of a cell transistor connected to the other bit line BLa and an information storage element SP may be arranged in a direction opposite to the second horizontal direction (the Y direction). For example, the plurality of bit lines BLa may include a first bit line, a second bit line, a third bit line, and a fourth bit line, which are sequentially arranged adjacent to each other in the second horizontal direction (the Y direction), the memory cell MC may not be disposed between the first bit line and the second bit line, two memory cells MC may be disposed in the second horizontal direction (the Y direction) at the same vertical level, between the second bit line and the third bit line, and the memory cell MC may not be disposed between the third bit line and the fourth bit line.

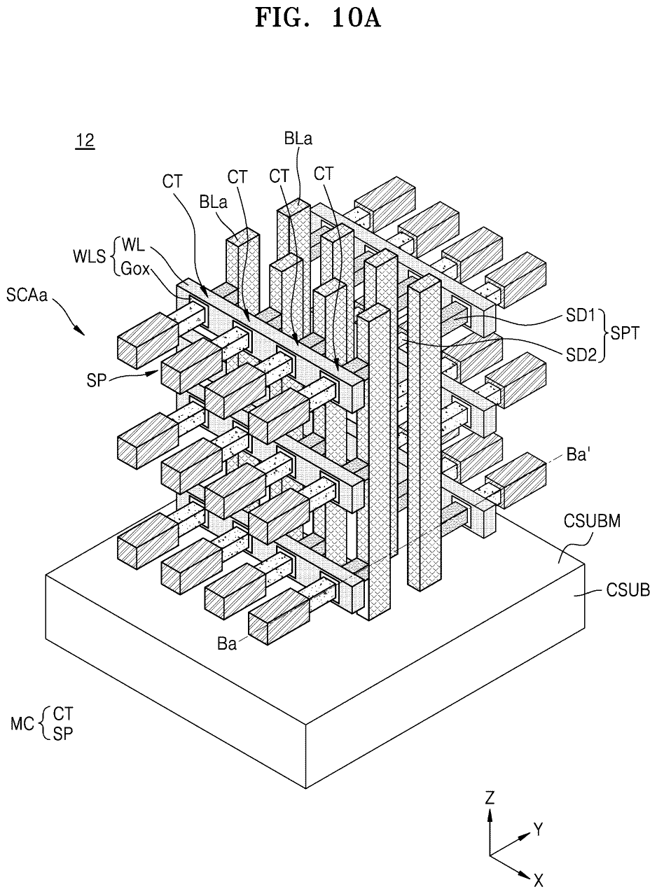

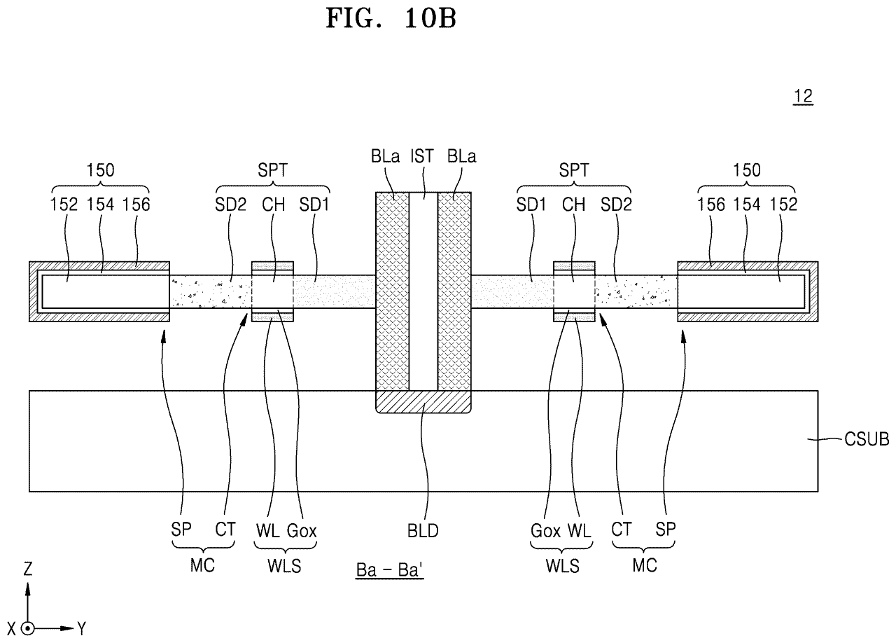

FIGS. 10A and 10B are a perspective view and a cross-sectional view illustrating a portion of a semiconductor memory device 12 according to embodiments. In detail, FIG. 10 is a perspective view illustrating an enlarged region corresponding to a region VA of FIG. 4 in the semiconductor memory device 12 illustrated in FIG. 9, and FIG. 10B is a cross-sectional view taken along line Ba-Ba′ of FIG. 10A.

Referring to FIGS. 10A and 10B, the semiconductor memory device 12 may include a cell substrate CSUB and a plurality of sub cell arrays SCAa. The plurality of sub cell arrays SCAa may be arranged in a second horizontal direction (a Y direction). The sub cell array SCAa may include the cell substrate CSUB, a plurality of word lines WL which are apart from a main surface CSUBM of the cell substrate CSUB and are disposed on the cell substrate CSUB, a plurality of bit lines BLa which extend in a vertical direction (a Z direction) from the main surface CSUBM of the cell substrate CSUB, a plurality of cell transistors CT which are disposed between the plurality of word lines WL and the plurality of bit lines BLa, and a plurality of information storage elements SP which are connected to the plurality of cell transistors CT. The plurality of cell transistors CT and the plurality of information storage elements SP may configure a plurality of memory cells MC.

The plurality of word lines WL may extend in a first horizontal direction (an X direction) on the cell substrate CSUB and may be apart from one another in each of a second horizontal direction (a Y direction) and the vertical direction (the Z direction). The plurality of bit lines BLa may extend in the vertical direction (the Z direction) from the cell substrate CSUB and may be apart from one another in each of the first horizontal direction (the X direction) and the second horizontal direction (the Y direction).

One cell transistor CT may be disposed between one word line WL and one bit line BLa. The information storage element SP may be connected to the cell transistor CT. The cell transistor CT and the information storage element SP may be sequentially arranged in the second horizontal direction (the Y direction) or an opposite direction of the second horizontal direction (the Y direction) from a bit line BLa connected to the cell transistor CT.

The source region SD1, the channel region CH, and the drain region SD2 may be sequentially arranged in the second horizontal direction (the Y direction) or the opposite direction of the second horizontal direction (the Y direction) from the bit line BLa. Two sub cell arrays SCAa adjacent to each other in the second horizontal direction (the Y direction) may not share bit lines BLa. A source region SD1, a channel region CH, and a drain region SD2 of a cell transistor CT connected to each of two bit lines BLa adjacent to each other in the second horizontal direction (the Y direction) and an information storage element SP may be disposed in opposite directions.

For example, a source region SD1, a channel region CH, and a drain region SD2 of a cell transistor CT connected to one of two bit lines BLa adjacent to each other in the second horizontal direction (the Y direction) and an information storage element SP may be sequentially arranged in the second horizontal direction (the Y direction), and a source region SD1, a channel region CH, and a drain region SD2 of a cell transistor CT connected to the other bit line BLa and an information storage element SP may be arranged in a direction opposite to the second horizontal direction (the Y direction).

The bit line BLa may be apart from the cell substrate CSUB. A separation insulation layer BLD may be disposed between the cell substrate CSUB and the bit line BLa. The bit line BLa may be disposed on the separation insulation layer BLD. The separation insulation layer BLD may electrically insulate the cell substrate CSUB from the bit line BLa. At least a portion of the separation insulation layer BLD may be buried in the cell substrate CSUB.

A pair of bit lines BLa adjacent to each other in the second horizontal direction (the Y direction) may be disposed on one separation insulation layer BLD. The pair of bit lines BLa disposed on the one separation insulation layer BLD may be apart from each other with an insulation structure IST therebetween. A pair of bit lines BLa adjacent to each other in the second horizontal direction (the Y direction) and the insulation structure IST filling a region between the pair of bit lines BLa may be disposed on one separation insulation layer BLD.

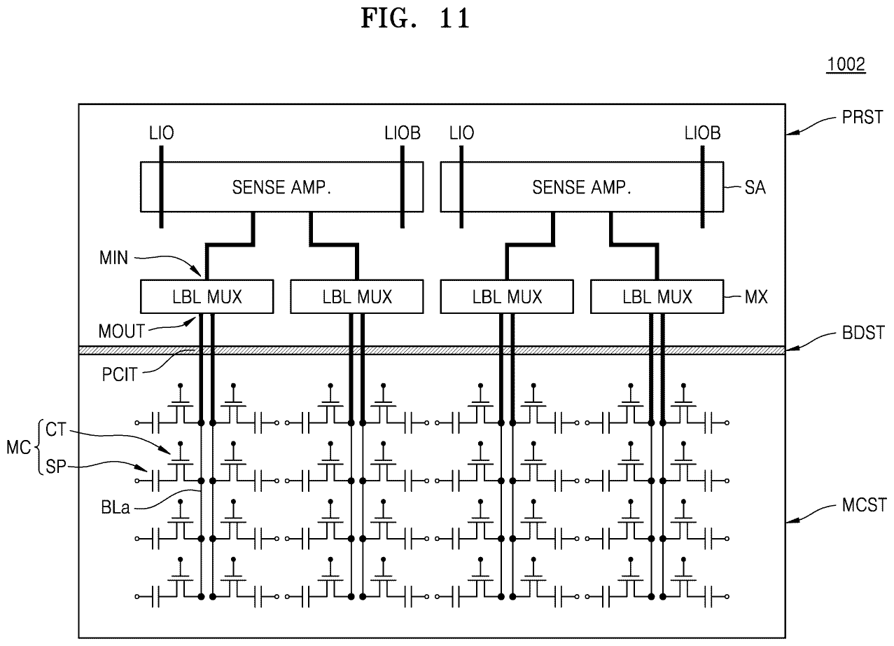

FIG. 11 is a diagram for describing a semiconductor memory device 1002 according to embodiments.

Referring to FIG. 11, the semiconductor memory device 1002 may include a memory cell structure MCST and a peripheral circuit structure PRST, which are stacked in a vertical direction (a Z direction). A bonding structure BDST may be disposed between the memory cell structure MCST and the peripheral circuit structure PRST.

The memory cell structure MCST and the peripheral circuit structure PRST may be electrically connected to each other by a circuit cell connection structure PCIT. Each of a plurality of circuit cell connection structures PCIT may pass through the bonding structure BDST and may extend into each of the memory cell structure MCST and the peripheral circuit structure PRST.

The peripheral circuit structure PRST may include a plurality of peripheral circuit transistors. The plurality of peripheral circuit transistors may be configured to transfer a signal and/or power to a plurality of memory cells included in the memory cell structure MCST. For example, the plurality of peripheral circuit transistors may configure various circuits such as a command decoder, a control logic, an address buffer, a row decoder, a column decoder, a sense amplifier SA, a multiplexer MX, and a data I/O circuit. In FIG. 11, the sense amplifier SA and the multiplexer MX of the various circuits configured by the plurality of peripheral circuit transistors are illustrated.

A local I/O line LIO and a local I/O line bar LIOB may be connected to the sense amplifier SA. A sense amplifier SA may be electrically connected to two bit lines BLa of a plurality of bit lines BLa. The multiplexer MX may be disposed between the sense amplifier SA and the bit line BLa. Two multiplexers MX may be connected to one sense amplifier SA. One sense amplifier SA may be electrically connected to a bit line BLa selected through two multiplexers MX and the bit line BLa to which the reference voltage has been supplied.

The multiplexer MX may include one sense amplifier connection terminal MIN and two bit line connection terminals MOUT. The sense amplifier connection terminal MIN of the multiplexer MX may be connected to the sense amplifier SA, and the bit line connection terminal MOUT of the multiplexer MX may be connected to the bit line BLa. The bit line connection terminal MOUT of the multiplexer MX and the bit line BLa may be connected to each other through the circuit cell connection structure PCIT. When the multiplexer MX is a 2*1 multiplexer, the multiplexer MX may include two bit line connection terminals MOUT and may be connected to two bit lines BLa, and moreover, may be electrically connected to one bit line BLa selected from among the two bit lines BLa. Therefore, the sense amplifier SA may be connected to four bit lines BLa through two multiplexers MX and may be electrically connected to two bit lines BLa which are selected by the two multiplexers MX from among the four bit lines BLa.

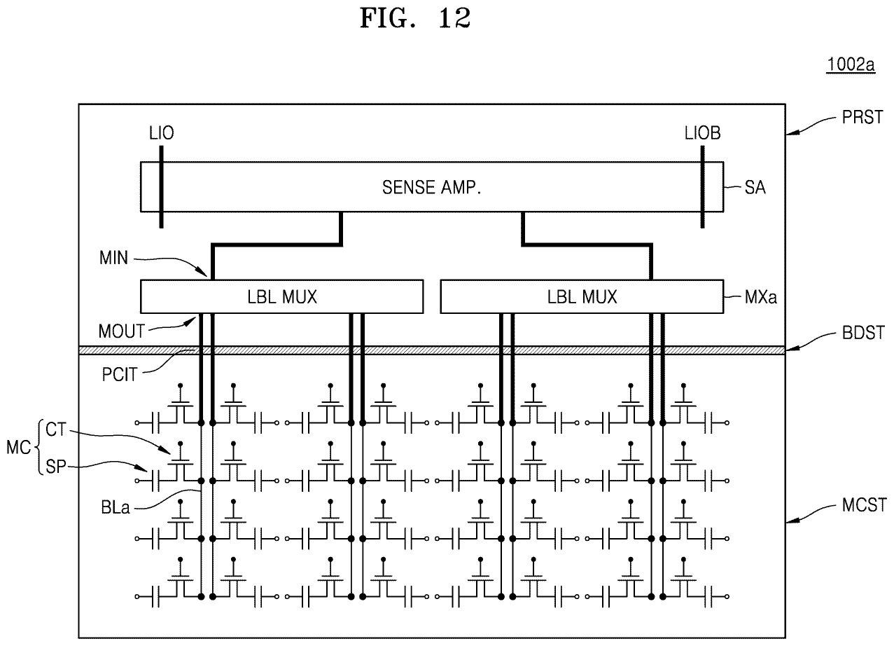

FIG. 12 is a diagram for describing a semiconductor memory device 1002a according to embodiments.

Referring to FIG. 12, the semiconductor memory device 1002a may include a memory cell structure MCST and a peripheral circuit structure PRST, which are stacked in a vertical direction (a Z direction). A bonding structure BDST may be disposed between the memory cell structure MCST and the peripheral circuit structure PRST.

The memory cell structure MCST and the peripheral circuit structure PRST may be electrically connected to each other by a circuit cell connection structure PCIT. Each of a plurality of circuit cell connection structures PCIT may pass through the bonding structure BDST and may extend into each of the memory cell structure MCST and the peripheral circuit structure PRST.

The peripheral circuit structure PRST may include a plurality of peripheral circuit transistors. The plurality of peripheral circuit transistors may be configured to transfer a signal and/or power to a plurality of memory cells included in the memory cell structure MCST. For example, the plurality of peripheral circuit transistors may configure various circuits such as a command decoder, a control logic, an address buffer, a row decoder, a column decoder, a sense amplifier SA, a multiplexer MXa, and a data I/O circuit. In FIG. 12, the sense amplifier SA and the multiplexer MXa of the various circuits configured by the plurality of peripheral circuit transistors are illustrated.

A local I/O line LIO and a local I/O line bar LIOB may be connected to the sense amplifier SA. A sense amplifier SA may be electrically connected to two bit lines BLa of a plurality of bit lines BLa. The multiplexer MXa may be disposed between the sense amplifier SA and the bit line BLa. Two multiplexers MXa may be connected to one sense amplifier SA. One sense amplifier SA may be electrically connected to a bit line BLa selected through two multiplexers MXa and the bit line BLa to which the reference voltage has been supplied.

The multiplexer MXa may include one sense amplifier connection terminal MIN and four or more bit line connection terminals MOUT. The sense amplifier connection terminal MIN of the multiplexer MXa may be connected to the sense amplifier SA, and the bit line connection terminal MOUT of the multiplexer MXa may be connected to the bit line BLa. The bit line connection terminal MOUT of the multiplexer MXa and the bit line BLa may be connected to each other through the circuit cell connection structure PCIT. The multiplexer MXa may be a 4*1 multiplexer, an 8*1 multiplexer, a 10*1 multiplexer, a 12*1 multiplexer, a 14*1 multiplexer, or a 16*1 multiplexer, and for example, may include four or more bit line connection terminals MOUT. For example, when the multiplexer MXa is a 4*1 multiplexer, the multiplexer MXa may include four bit line connection terminals MOUT and may be connected to four bit lines BLa, and moreover, may be electrically connected to one bit line BLa selected from among the four bit lines BLa. Therefore, the sense amplifier SA may be connected to eight or more bit lines BLa through two multiplexers MX and may be electrically connected to two bit lines BLa which are selected by the two multiplexers MXa from among the eight or more bit lines BLa. One of two bit lines BLa electrically connected to the sense amplifier SA may be one bit line BLa which is selected for reading or writing data, and the other bit line BLa may be a bit line BLa to which the reference voltage has been supplied.

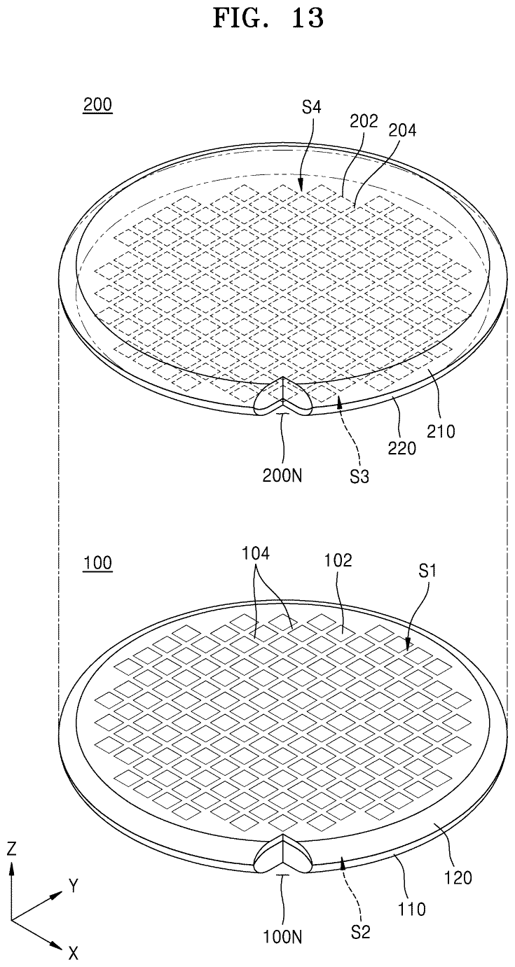

FIG. 13 is a diagram for describing a method of manufacturing a semiconductor memory device, according to embodiments.

Referring to FIG. 13, a first wafer 100 may include a plurality of first dies 102 and a first scribe lane region 104 which extends along a region between the plurality of first dies 102. The first wafer 100 may include a first surface S1 and a second surface S2 opposite to each other. A second wafer 200 may include a plurality of second dies 202 and a second scribe lane region 204 which extends along a region between the plurality of second dies 202. The second wafer 200 may include a third surface S3 and a fourth surface S4 opposite to each other.

The first wafer 100 may include a memory layer 110 and a first bonding layer 120 covering the memory layer 110, and the second wafer 200 may include a peripheral circuit layer 210 and a second bonding layer 220 covering the peripheral circuit layer 210. The first bonding layer 120 may be disposed at a first surface S1 side of the first wafer 100, and the memory layer 110 may be disposed at a second surface S2 side of the first wafer 100. The second bonding layer 220 may be disposed at a third surface S3 side of the second wafer 200, and the peripheral circuit layer 210 may be disposed at a fourth surface S4 side of the second wafer 200.

A portion of the memory layer 110 of each of a plurality of first dies 102 may correspond to the memory cell structure MCST of each of FIGS. 3, 6A, 6B, 8, 11, and 12. A portion of the peripheral circuit layer 210 of each of a plurality of second dies 202 may correspond to the peripheral circuit structure PRST of each of FIGS. 3, 6A, 6B, 7A, 7B, 8, 11, and 12. A portion of the first bonding layer 120 of each of the plurality of first dies 102 may correspond to a portion, which is adjacent to the memory cell structure MCST, of the bonding structure BDST of each of FIGS. 3, 6A, 6B, 8, 11, and 12 and may correspond to a portion, which is adjacent to the memory cell structure MCST, of the bonding structure BDSTa of FIGS. 7A and 7B. A portion of the second bonding layer 220 of each of the plurality of second dies 202 may correspond to a portion, which is adjacent to the peripheral circuit structure PRST, of the bonding structure BDST of each of FIGS. 3, 6A, 6B, 7A, 7B, 8, 11, and 12 and may correspond to a portion, which is adjacent to the peripheral circuit structure PRST, of the bonding structure BDSTa of FIGS. 7A and 7B.

The first surface S1 of the first wafer 100 and the third surface S3 of the second wafer 200 may face each other, and the first wafer 100 and the second wafer 200 may be bonded to each other. The first wafer 100 and the second wafer 200 may be bonded to each other so that the plurality of first dies 102 and the plurality of second dies 202 corresponding to each other overlap each other. The first bonding layer 120 of the first wafer 100 and the second bonding layer 220 of the second wafer 200 may be bonded to each other, and thus, the bonding structure BDST of each of FIGS. 3, 6A, 6B, 8, 11, and 12 and the bonding structure BDSTa of FIGS. 7A and 7B may be formed. The first wafer 100 and the second wafer 200 may be bonded to each other by a hybrid bonding process or a direct bonding process.

Subsequently, the first wafer 100 and the second wafer 200 bonded to each other may be diced along the first scribe lane region 104 and the second scribe lane region 204, thereby forming a plurality of semiconductor memory devices including the plurality of first dies 102 and the plurality of second dies 202 corresponding to each other. Each of the plurality of semiconductor memory devices may be one of the semiconductor memory device 1000 illustrated in FIG. 3, the semiconductor memory device 1 illustrated in FIGS. 6A and 6B, the semiconductor memory device 2 illustrated in FIGS. 7A and 7B, the semiconductor memory device 1000a illustrated in FIG. 8, the semiconductor memory device 1002 illustrated in FIG. 11, and the semiconductor memory device 1002a illustrated in FIG. 12. In some embodiments, the first wafer 100 may include a first notch 100N, and the second wafer 200 may include a second notch 200N.

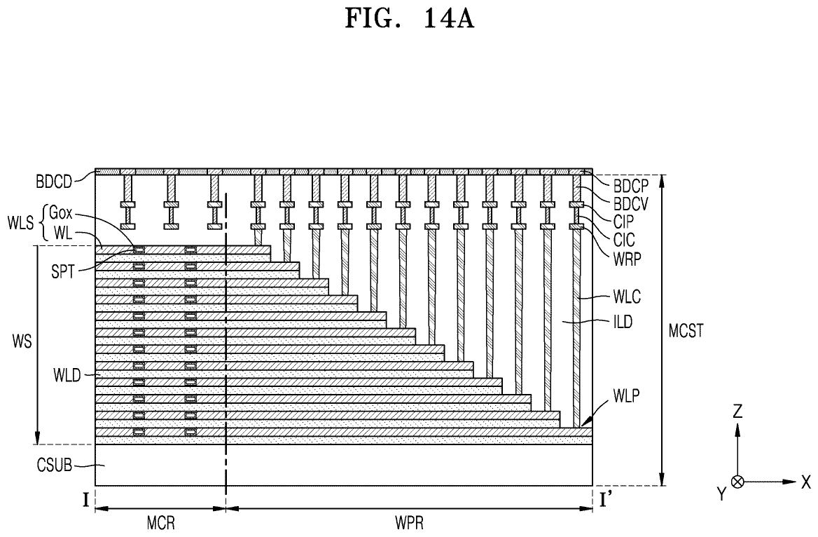

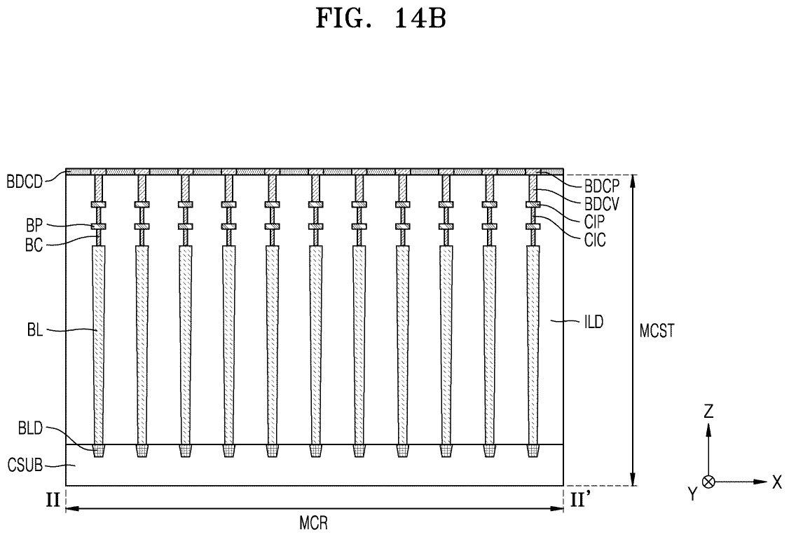

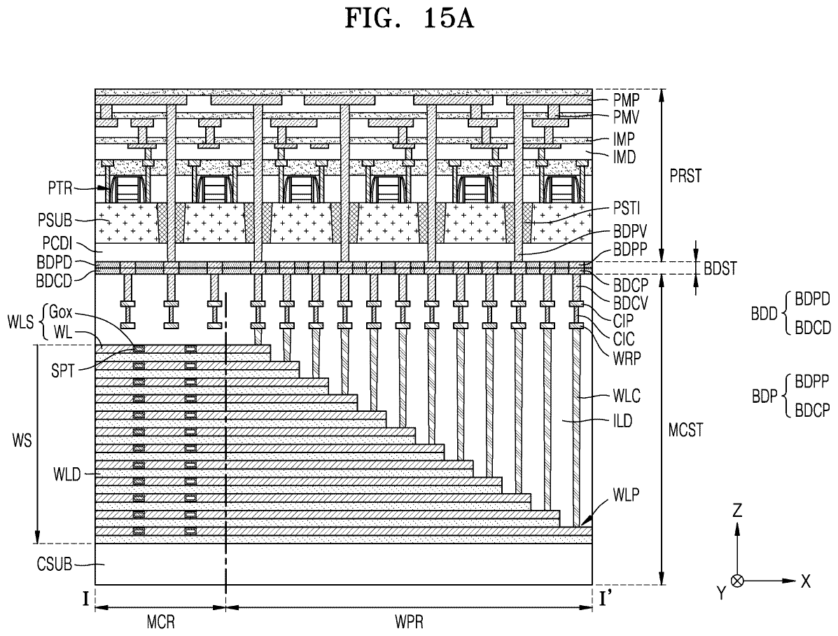

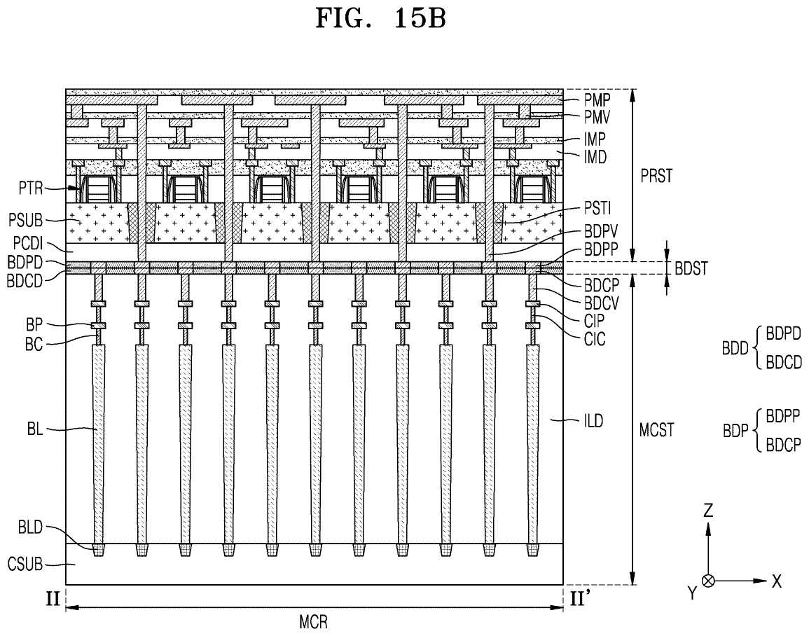

FIGS. 14A, 14B, 15A, and 15B are cross-sectional views for describing a method of manufacturing a semiconductor memory device, according to embodiments. In detail, FIGS. 14A, 14B, 15A, and 15B are cross-sectional views for describing a method of manufacturing the semiconductor memory device 1 illustrated in FIGS. 6A and 6B, and in describing FIGS. 14A, 14B, 15A, and 15B, descriptions overlapping the descriptions of FIGS. 6A and 6B may be omitted.

Referring to FIGS. 14A and 14B, a memory cell structure MCST may be formed, and then, a plurality of cell bonding pads BDCP and a cell bonding insulation layer BDCD surrounding the plurality of cell bonding pads BDCP may be formed on the memory cell structure MCST. The cell bonding insulation layer BDCD may be formed to cover the memory cell structure MCST. For example, the cell bonding insulation layer BDCD may be formed to cover an upper surface of the memory cell structure MCST.

A plurality of word lines WL which extend in a first horizontal direction (an X direction) and are apart from each other in a second horizontal direction (a Y direction) and a vertical direction (a Z direction), a plurality of semiconductor patterns SPT which are adjacent to the plurality of word lines WL, extend in the second horizontal direction (the Y direction), and are apart from each other in the first horizontal direction (the X direction) and the vertical direction (the Z direction), a plurality of bit lines which extend in the vertical direction (the Z direction), are apart from each other in the first horizontal direction (the X direction) and the second horizontal direction (the Y direction), and are connected to the plurality of semiconductor patterns SPT, a plurality of word line contacts WLC which are connected to a plurality of word line pad parts WLP included in the plurality of word lines WL and extend in the vertical direction (the Z direction), and an interlayer insulation layer ILD surrounding the plurality of word lines WL, the plurality of bit lines BL, and the plurality of word line contacts WLC may be formed on a cell substrate CSUB, thereby forming the memory cell structure MCST.

The plurality of cell bonding pads BDCP may be formed on the interlayer insulation layer ILD so as to be connected to a plurality of cell bonding vias BDCV disposed on a plurality of cell connection patterns CIP, and the cell bonding insulation layer BDCD may be formed on the interlayer insulation layer ILD to surround side surfaces of the plurality of cell bonding pads BDCP. The plurality of cell bonding pads BDCP may be electrically connected to the plurality of word lines WL and the plurality of bit lines BL. The memory cell structure MCST may be a portion of each of the plurality of first dies 102 in the memory layer 110 of the first wafer 100 illustrated in FIG. 13, and each of the plurality of cell bonding pads BDCP and the cell bonding insulation layer BDCD each disposed on the memory cell structure MCST may be a portion of each of the plurality of first dies 102 in the first bonding layer 120 of the first wafer 100 illustrated in FIG. 13.

Referring to FIGS. 15A and 15B, a peripheral circuit structure PRST may be formed, and then, a plurality of peripheral circuit bonding pads BDPP and a peripheral circuit bonding insulation layer BDPD surrounding the plurality of peripheral circuit bonding pads BDPP may be formed under the peripheral circuit structure PRST. The peripheral circuit bonding insulation layer BDPD may be formed to cover the peripheral circuit structure PRST. For example, the peripheral circuit bonding insulation layer BDPD may be formed to cover a lower surface of the peripheral circuit structure PRST.

The peripheral circuit structure PRST may be formed to include a peripheral circuit substrate PSUB and a plurality of peripheral circuit transistors PTR. The plurality of peripheral circuit transistors PTR may be formed to be disposed on upper surfaces of portions of the peripheral circuit substrate PSUB defined by a device isolation insulation layer PSTI. The plurality of peripheral circuit transistors PTR may be configured to transfer a signal and/or power to the plurality of memory cells MC included in the memory cell structure MCST. For example, the plurality of peripheral circuit transistors PTR may configure various circuits such as a command decoder, a control logic, an address buffer, a row decoder, a column decoder, a sense amplifier, a multiplexer, and a data I/O circuit. For example, some of the plurality of peripheral circuit transistors PTR may be formed to configure the sense amplifier SA and the multiplexer MX each illustrated in FIG. 3.

The peripheral circuit structure PRST may be formed to further include a plurality of peripheral circuit connection patterns PMP on the peripheral circuit substrate PSUB, a plurality of peripheral circuit connection vias PMV connected to the plurality of peripheral circuit connection patterns PMP, a peripheral circuit wiring insulation layer IMD which surrounds the plurality of peripheral circuit connection patterns PMP and the plurality of peripheral circuit connection vias PMV and covers the peripheral circuit substrate PSUB, and a peripheral circuit wiring protection layer IMP which covers the plurality of peripheral circuit connection patterns PMP and the peripheral circuit wiring insulation layer IMD.

The plurality of peripheral circuit bonding pads BDPP may be formed under the peripheral circuit substrate PSUB so as to be connected to a plurality of peripheral circuit bonding vias BDPV connected to the peripheral circuit connection pattern PMP, and the peripheral circuit bonding insulation layer BDPD may be formed under the peripheral circuit substrate PSUB to surround side surfaces of the plurality of peripheral circuit bonding pads BDPP. The plurality of peripheral circuit bonding pads BDPP may be electrically connected to the plurality of peripheral circuit transistors PTR. In some embodiments, before forming the plurality of peripheral circuit bonding pads BDPP and the peripheral circuit bonding insulation layer BDPD, a peripheral circuit cover insulation layer PCDI covering a lower surface of the peripheral circuit substrate PSUB may be formed, and the plurality of peripheral circuit bonding vias BDPV passing through the peripheral circuit wiring insulation layer IMD, the peripheral circuit wiring protection layer IMP, and/or a device isolation insulation layer PSTI may be formed, and then, the plurality of peripheral circuit bonding pads BDPP and the peripheral circuit bonding insulation layer BDPD may be formed on a lower surface of the peripheral circuit cover insulation layer PCDI.

The peripheral circuit structure PRST may be a portion of each of the plurality of second dies 202 in the peripheral circuit layer 210 of the second wafer 200 illustrated in FIG. 13, and each of the plurality of peripheral circuit bonding pads BDPP disposed under the peripheral circuit structure PRST and the peripheral circuit bonding insulation layer BDPD surrounding the plurality of peripheral circuit bonding pads BDPP may be a portion of each of the plurality of second dies 202 in the second bonding layer 220 of the second wafer 200 illustrated in FIG. 13.

Subsequently, a corresponding cell bonding pad of a plurality of cell bonding pads BDCP and a corresponding peripheral circuit bonding pad of the plurality of peripheral circuit bonding pads BDPP may be bonded to each other to correspond to each other, and the peripheral circuit structure PRST may be disposed on the memory cell structure MCST to contact a cell bonding insulation layer BDCD and the peripheral circuit bonding insulation layer BDPD, and then, the memory cell structure MCST may be bonded to the peripheral circuit structure PRST by applying heat and pressure. The cell bonding insulation layer BDCD and the peripheral circuit bonding insulation layer BDPD may be bonded to each other to form a covalent bond and may thus configure a bonding insulation layer BDD, and the plurality of cell bonding pads BDCP and the plurality of peripheral circuit bonding pads BDPP corresponding to each other may face each other and may expand based on heat to be bonded to each other and may be bonded to each other through diffusion bonding to configure one body, based on diffusion of metal atoms included therein, and thus, may configure a plurality of bonding pads BDP, thereby forming a bonding structure BDST.

Subsequently, an external connection pad structure PDST, which includes the plurality of external connection pads EPD illustrated in FIGS. 6A and 6B, a plurality of external connection vias EPV connecting the plurality of external connection pads EPD to the plurality of peripheral circuit connection patterns PMP, a cover insulation layer CDI surrounding the plurality of external connection pads EPD and the plurality of external connection vias EPV, and a protection insulation layer PSV which covers the cover insulation layer CDI and does not cover at least partial portions of upper surfaces of the plurality of external connection pads EPD, may be formed on the peripheral circuit structure PRST, thereby forming the semiconductor memory device 1.

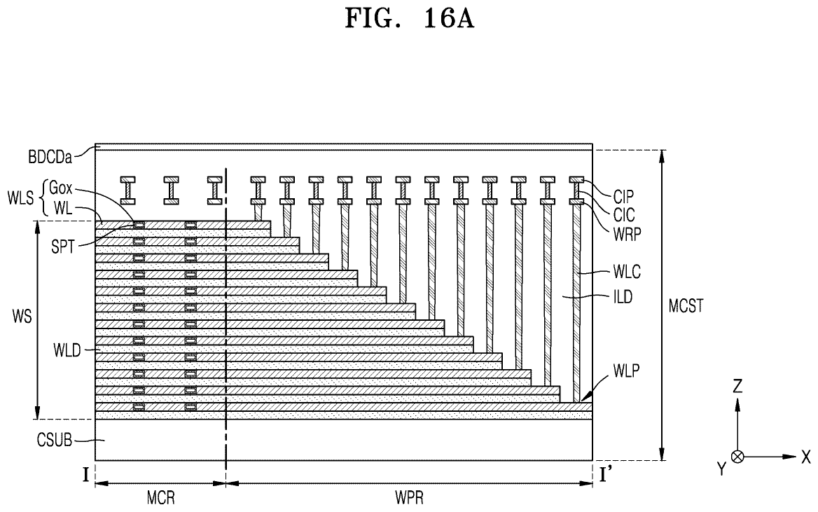

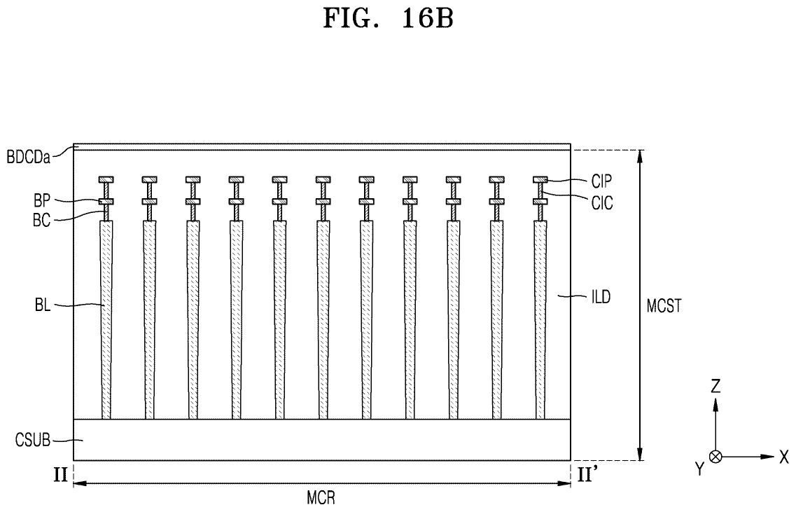

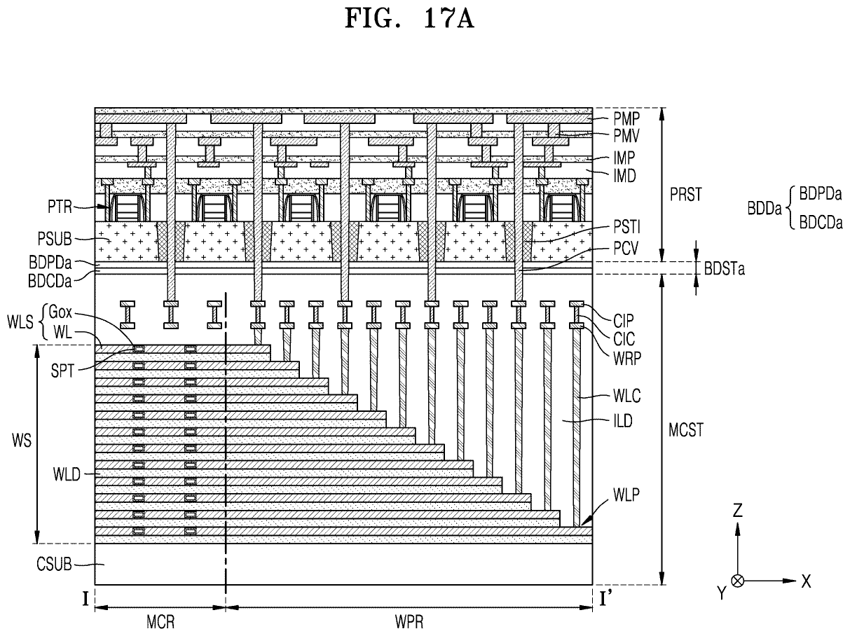

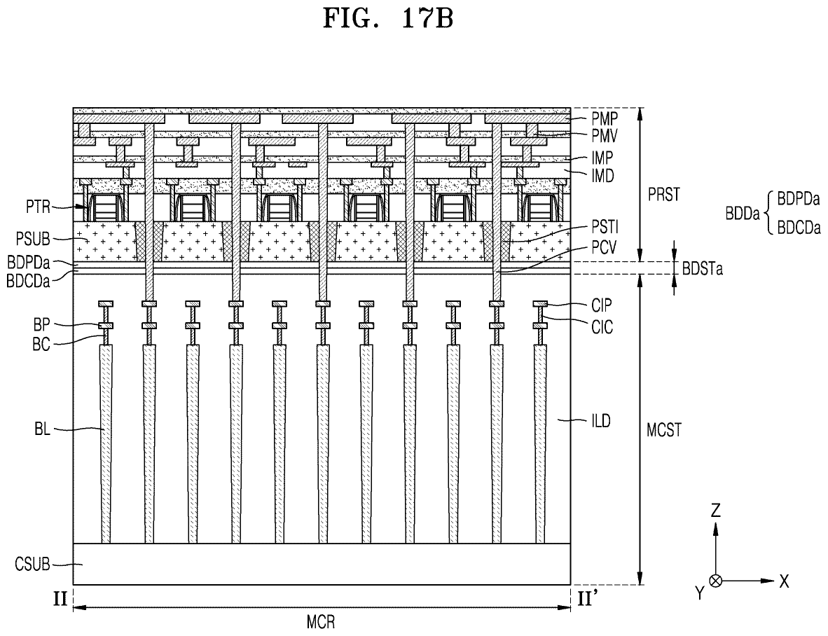

FIGS. 16A, 16B, 17A, and 17B are cross-sectional views for describing a method of manufacturing a semiconductor memory device, according to embodiments. In detail, FIGS. 16A, 16B, 17A, and 17B are cross-sectional views for describing a method of manufacturing the semiconductor memory device 1 illustrated in FIGS. 7A and 7B, and in describing FIGS. 16A, 16B, 17A, and 17B, descriptions overlapping the descriptions of FIGS. 7A and 7B may be omitted.

Referring to FIGS. 16A and 16B, a memory cell structure MCST may be formed, and then, a cell bonding insulation layer BDCDa may be formed on the memory cell structure MCST. The cell bonding insulation layer BDCDa may be formed to cover an interlayer insulation layer ILD. The memory cell structure MCST may be a portion of each of the plurality of first dies 102 in the memory layer 110 of the first wafer 100 illustrated in FIG. 13, and the cell bonding insulation layer BDCDa each disposed on the memory cell structure MCST may be a portion of each of the plurality of first dies 102 in the first bonding layer 120 of the first wafer 100 illustrated in FIG. 13.

Referring to FIGS. 17A and 17B, at least a portion of a peripheral circuit structure PRST may be formed, and then, a peripheral circuit bonding insulation layer BDPDa may be formed under the peripheral circuit structure PRST. For example, a peripheral circuit substrate PSUB, a device isolation insulation layer PSTI, and a plurality of peripheral circuit transistors PTR of the peripheral circuit structure PRST may be formed, at least a portion of each of a peripheral circuit wiring insulation layer IMD, and a peripheral circuit wiring protection layer IMP, a plurality of peripheral circuit connection patterns PMP, and a plurality of peripheral circuit connection vias PMV may be formed, and then, a peripheral circuit bonding insulation layer BDPDa covering a lower surface of the peripheral circuit substrate PSUB may be formed.

Subsequently, the peripheral circuit structure PRST may be disposed on the memory cell structure MCST to contact a cell bonding insulation layer BDCDa and the peripheral circuit bonding insulation layer BDPDa, and then, the peripheral circuit structure PRST may be bonded to the memory cell structure MCST by applying heat and pressure. The cell bonding insulation layer BDCDa and the peripheral circuit bonding insulation layer BDPDa may form a covalent bond and may be bonded to each other to configure a bonding insulation layer BDDa, thereby forming a bonding structure BDSTa.

After the bonding structure BDSTa is formed, a plurality of circuit cell connection vias PCV passing through the bonding structure BDSTa may be formed, and the other portion of each of the peripheral circuit wiring insulation layer IMD, the peripheral circuit wiring protection layer IMP, the plurality of peripheral circuit connection patterns PMP, and the plurality of peripheral circuit connection vias PMV may be formed, thereby forming the peripheral circuit structure PRST. The plurality of circuit cell connection vias PCV may pass through at least a portion of the peripheral circuit wiring insulation layer IMD and/or the peripheral circuit wiring protection layer IMP, the device isolation insulation layer PSTI and the bonding insulation layer BDDa, and a portion of an interlayer insulation layer ILD and may connect the peripheral circuit connection pattern PMP to a cell connection pattern CIP. The peripheral circuit structure PRST may be a portion of each of the plurality of second dies 202 in the peripheral circuit layer 210 of the second wafer 200 illustrated in FIG. 13, and the peripheral circuit bonding insulation layer BDPDa disposed under the peripheral circuit structure PRST may be a portion of each of the plurality of second dies 202 in the second bonding layer 220 of the second wafer 200 illustrated in FIG. 13.

Subsequently, an external connection pad structure PDST, which includes the plurality of external connection pads EPD illustrated in FIGS. 7A and 7B, a plurality of external connection vias EPV connecting the plurality of external connection pads EPD to the plurality of peripheral circuit connection patterns PMP, a cover insulation layer CDI surrounding the plurality of external connection pads EPD and the plurality of external connection vias EPV, and a protection insulation layer PSV which covers the cover insulation layer CDI and does not cover at least partial portions of upper surfaces of the plurality of external connection pads EPD, may be formed on the peripheral circuit structure PRST, thereby forming the semiconductor memory device 2.

A method of manufacturing a semiconductor memory device, according to an embodiment, includes forming a cell bonding insulation layer covering a memory cell structure, forming a peripheral circuit bonding insulation layer covering a peripheral circuit structure, and forming a bonding structure including a bonding insulation layer where the cell bonding insulation layer is bonded to the peripheral circuit bonding insulation layer, and forming the memory cell structure, the bonding structure, and the peripheral circuit structure, which are stacked in a vertical direction, wherein the memory cell structure includes a plurality of memory cells configured by a plurality of word lines each extending in a first horizontal direction and arranged apart from one another to configure a column in each of a second horizontal direction perpendicular to the first horizontal direction and a vertical direction, a plurality of semiconductor patterns which are adjacent to the plurality of word lines, each extend in the second horizontal direction, and are arranged to configure a column in each of the first horizontal direction, the second horizontal direction, and the vertical direction, a plurality of bit lines which each extend in the vertical direction, are arranged apart from one another to configure a column in each of the first horizontal direction and the second horizontal direction, and are connected to ends of the plurality of semiconductor patterns in the second horizontal direction, and a plurality of information storage elements connected to the other ends of the plurality of semiconductor patterns, the peripheral circuit structure is stacked in the vertical direction with respect to the memory cell structure and includes a peripheral circuit substrate, a device isolation insulation layer buried in the peripheral circuit substrate and a plurality of peripheral circuit transistors disposed in portions of the peripheral circuit substrate defined by the device isolation insulation layer, the plurality of peripheral circuit transistors configuring a sense amplifier, and a first multiplexer and a second multiplexer each connected to the sense amplifier, the first multiplexer being electrically connected to at least two of the plurality of bit lines, and the second multiplexer being electrically connected to at least two other bit lines among the plurality of bit lines, and the bonding structure includes a plurality of circuit cell connection structures which pass through the bonding insulation layer and electrically connect the first multiplexer and the second multiplexer to the plurality of bit lines.

In embodiments, each of the plurality of circuit cell connection structures may be formed to extend in the vertical direction from the bonding insulation layer to each of the memory cell structure and the peripheral circuit structure.

In embodiments, each of the plurality of circuit cell connection structures may be formed to have a tapered shape which extends and have a horizontal width narrowing in the vertical direction from the peripheral circuit structure to the memory cell structure.

In embodiments, each of the plurality of circuit cell connection structures may be formed to include a bonding pad surrounded by the bonding insulation layer, a cell bonding via extending in the vertical direction from the bonding pad to the memory cell structure, and a peripheral circuit bonding via extending in the vertical direction from the bonding pad to the peripheral circuit structure.

In embodiments, a cell bonding pad surrounded by the cell bonding insulation layer and a peripheral circuit bonding pad surrounded by the peripheral circuit bonding insulation layer may face each other, and may expand based on heat to contact each other, and the cell bonding pad and the peripheral circuit bonding pad may be bonded to each other through diffusion bonding, based on diffusion of metal atoms included therein, and thus, the bonding pad may be formed.

In embodiments, each of the plurality of cell transistors may include a semiconductor pattern extending in the second horizontal direction, each of the plurality of bit lines may be formed to be connected to one end of the semiconductor pattern in the second horizontal direction, and each of the plurality of information storage elements may be formed to be connected to the other end of the semiconductor pattern in the second horizontal direction.

In embodiments, each of the plurality of information storage elements may be formed to include a first electrode contacting each of the plurality of semiconductor patterns, a capacitor dielectric layer covering the first electrode, and a second electrode covering the capacitor dielectric layer.

In embodiments, each of the first multiplexer and the second multiplexer may include one sense amplifier connection terminal connected to the sense amplifier and at least two bit line connection terminals connected to one of the plurality of bit lines.

In embodiments, the peripheral circuit structure may be formed to include a peripheral circuit substrate and a device isolation insulation layer buried in the peripheral circuit substrate, the plurality of peripheral circuit transistors may be formed to be disposed in portions of the peripheral circuit substrate defined by the device isolation insulation layer, and the plurality of circuit cell connection structures may be formed to pass through the device isolation insulation layer.

In embodiments, the sense amplifier may be electrically connected to one of at least two bit lines among the plurality of bit lines through the first multiplexer and may be electrically connected to one of at least two other bit lines among the plurality of bit lines through the second multiplexer.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While the inventive concept has been particularly shown and described with reference to embodiments thereof, it will be understood that various changes in form and details may be made therein without departing from the spirit and scope of the following claims.

What is claimed is:

1. A semiconductor memory device comprising:
a memory cell structure including a plurality of memory cells configured by a plurality of semiconductor patterns, a plurality of word lines adjacent to the plurality of semiconductor patterns, a plurality of bit lines connected to the plurality of semiconductor patterns, and a plurality of information storage elements connected to the plurality of semiconductor patterns, the plurality of information storage elements arranged to configure a column in each of a first horizontal direction, a second horizontal direction perpendicular to the first horizontal direction, and a vertical direction;
a peripheral circuit structure stacked in the vertical direction with respect to the memory cell structure and including a plurality of peripheral circuit transistors configuring a sense amplifier, and a first multiplexer and a second multiplexer each connected to the sense amplifier; and
a bonding structure including a bonding insulation layer and a plurality of circuit cell connection structures passing through the bonding insulation layer, and disposed between the memory cell structure and the peripheral circuit structure to bond the memory cell structure to the peripheral circuit structure,
wherein the first multiplexer is electrically connected to at least two bit lines among the plurality of bit lines through one or more of the plurality of circuit cell connection structures, and
the second multiplexer is electrically connected to at least two other bit lines among the plurality of bit lines through another one or more of the plurality of circuit cell connection structures.

2. The semiconductor memory device of claim 1, wherein one of the plurality of circuit cell connection structures extends in the vertical direction from the bonding insulation layer to each of the memory cell structure and the peripheral circuit structure.

3. The semiconductor memory device of claim 2, wherein the one of the plurality of circuit cell connection structures is configured to have a tapered shape which extends and has a horizontal width narrowing in the vertical direction from the peripheral circuit structure to the memory cell structure.

4. The semiconductor memory device of claim 1, wherein one of the plurality of circuit cell connection structures comprises a bonding pad surrounded by the bonding insulation layer, a cell bonding via extending in the vertical direction from the bonding pad to the memory cell structure, and a peripheral circuit bonding via extending in the vertical direction from the bonding pad to the peripheral circuit structure.

5. The semiconductor memory device of claim 1, wherein the plurality of semiconductor patterns are arranged to configure a column in each of the first horizontal direction, the second horizontal direction, and the vertical direction,
the plurality of word lines each extend in the first horizontal direction and are arranged apart from one another to configure a column in each of the second horizontal direction and the vertical direction, and
the plurality of bit lines each extend in the vertical direction and are arranged apart from one another to configure a column in each of the first horizontal direction and the second horizontal direction.

6. The semiconductor memory device of claim 5, wherein the plurality of bit lines are connected to ends of the plurality of semiconductor patterns in the second horizontal direction, and
the plurality of information storage elements are connected to other ends of the plurality of semiconductor patterns in the second horizontal direction.

7. The semiconductor memory device of claim 1, wherein the sense amplifier is electrically connected to, through the first multiplexer, one of the at least two bit lines among the plurality of bit lines and is electrically connected to, through the second multiplexer, one of the at least two other bit lines among the plurality of bit lines.

8. The semiconductor memory device of claim 7, wherein the one of the at least two bit lines among the plurality of bit lines electrically connected to the sense amplifier through the first multiplexer is connected to a memory cell selected for reading stored data or writing data from among the plurality of memory cells, and
a reference voltage is supplied to the one of the at least two other bit lines among the plurality of bit lines electrically connected to the sense amplifier through the second multiplexer.

9. The semiconductor memory device of claim 1, wherein each of the first multiplexer and the second multiplexer comprises one sense amplifier connection terminal connected to the sense amplifier and at least two bit line connection terminals connected to one of the plurality of bit lines.

10. The semiconductor memory device of claim 1, wherein one of the plurality of information storage elements is a capacitor structure including a first electrode contacting one of the plurality of semiconductor patterns, a capacitor dielectric layer covering the first electrode, and a second electrode covering the capacitor dielectric layer.

11. A semiconductor memory device comprising:
a memory cell structure including a plurality of memory cells configured by a plurality of word lines each extending in a first horizontal direction and arranged apart from one another to configure a column in each of a second horizontal direction perpendicular to the first horizontal direction and a vertical direction, a plurality of bit lines each extending in the vertical direction and arranged apart from one another to configure a column in each of the first horizontal direction and the second horizontal direction, a plurality of cell transistors disposed between the plurality of word lines and the plurality of bit lines and connected to the plurality of bit lines, and a plurality of information storage elements connected to the plurality of cell transistors;
a peripheral circuit structure stacked in the vertical direction with respect to the memory cell structure and including a plurality of peripheral circuit transistors configuring a sense amplifier, and a first multiplexer and a second multiplexer each connected to the sense amplifier; and
a bonding structure including a bonding insulation layer and a plurality of circuit cell connection structures passing through the bonding insulation layer, and disposed between the memory cell structure and the peripheral circuit structure to bond the memory cell structure to the peripheral circuit structure,
wherein the first multiplexer is electrically connected to at least two bit lines among the plurality of bit lines through one or more of the plurality of circuit cell connection structures, and the second multiplexer is electrically connected to at least two other bit lines among the plurality of bit lines through another one or more of the plurality of circuit cell connection structures.

12. The semiconductor memory device of claim 11, wherein each of the first multiplexer and the second multiplexer is a 2*1 multiplexer including one sense amplifier connection terminal connected to the sense amplifier and two bit line connection terminals connected to one of the plurality of bit lines.

13. The semiconductor memory device of claim 12, wherein the sense amplifier is connected through the first multiplexer and the second multiplexer to four bit lines among the plurality of bit lines.

14. The semiconductor memory device of claim 11, wherein the plurality of bit lines are connected to ends of the plurality of cell transistors in the second horizontal direction, and
the plurality of information storage elements are connected to other ends of the plurality of cell transistors in the second horizontal direction.

15. The semiconductor memory device of claim 11, wherein one of the plurality of circuit cell connection structures extends in the vertical direction from the bonding structure to each of the memory cell structure and the peripheral circuit structure.

16. The semiconductor memory device of claim 11, wherein the bonding insulation layer comprises a cell bonding insulation layer covering the memory cell structure and a peripheral circuit bonding insulation layer covering the peripheral circuit structure, and
the cell bonding insulation layer and the peripheral circuit bonding insulation layer are bonded to each other to form a covalent bond.

17. The semiconductor memory device of claim 11, wherein the peripheral circuit structure comprises a peripheral circuit substrate and a device isolation insulation layer buried in the peripheral circuit substrate,
the plurality of peripheral circuit transistors are disposed in portions of the peripheral circuit substrate defined by the device isolation insulation layer, and
the plurality of circuit cell connection structures pass through the device isolation insulation layer.

18. A semiconductor memory device comprising:
a memory cell structure including a plurality of memory cells configured by: a plurality of word lines each extending in a first horizontal direction and arranged apart from one another to configure a column in each of a second horizontal direction perpendicular to the first horizontal direction and a vertical direction; a plurality of semiconductor patterns which are adjacent to the plurality of word lines, each extend in the second horizontal direction, and are arranged to configure a column in each of the first horizontal direction, the second horizontal direction, and the vertical direction; a plurality of bit lines which each extend in the vertical direction, are arranged apart from one another to configure a column in each of the first horizontal direction and the second horizontal direction, and are connected to ends of the plurality of semiconductor patterns in the second horizontal direction; and a plurality of information storage elements connected to other ends of the plurality of semiconductor patterns;
a peripheral circuit structure stacked in the vertical direction with respect to the memory cell structure and including: a peripheral circuit substrate; a device isolation insulation layer buried in the peripheral circuit substrate; and a plurality of peripheral circuit transistors disposed in portions of the peripheral circuit substrate defined by the device isolation insulation layer, the plurality of peripheral circuit transistors configuring a sense amplifier, and a first multiplexer and a second multiplexer each connected to the sense amplifier; and
a bonding structure including: a bonding insulation layer; and a plurality of circuit cell connection structures which pass through the bonding insulation layer, extend in the vertical direction to each of the memory cell structure and the peripheral circuit structure, and disposed between the memory cell structure and the peripheral circuit structure to bond the memory cell structure to the peripheral circuit structure,
wherein the first multiplexer is electrically connected to at least two bit lines among the plurality of bit lines through one or more of the plurality of circuit cell connection structures, and the second multiplexer is electrically connected to at least two other bit lines among the plurality of bit lines through another one or more of the plurality of circuit cell connection structures.

19. The semiconductor memory device of claim 18, wherein one of the plurality of circuit cell connection structures includes a circuit cell connection via having a tapered shape which extends and has a horizontal width narrowing in the vertical direction from the peripheral circuit structure to the memory cell structure.

20. The semiconductor memory device of claim 18, wherein one of the at least two bit lines among the plurality of bit lines electrically connected to the sense amplifier through the first multiplexer is connected to a memory cell selected for reading stored data or writing data from among the plurality of memory cells, and
one of the at least two other bit lines among the plurality of bit lines electrically connected to the sense amplifier through the second multiplexer is supplied with a reference voltage and is connected to an unselected memory cell among the plurality of memory cells.
